(19) United States
(12) Patent Application Publication
(10) Pub. No.: US 2018/0094136 A1
(43) Pub. Date: Apr. 5, 2018

(54) LAMINATED MOLDED ARTICLE

(71) Applicant: ASAHI KASEI KABUSHIKI KAISHA, Tokyo (JP)

(72) Inventor: Yasuaki KONOMI, Tokyo (JP)

(73) Assignee: ASAHI KASEI KABUSHIKI KAISHA, Tokyo (JP)

(21) Appl. No.: 15/718,236

(22) Filed: Sep. 28, 2017

(30) Foreign Application Priority Data
Oct. 5, 2016 (JP) 2016-197646

(51) Int. Cl. C08L 85/02; C08J 5/00; C23C 14/24; B29C 45/00; C23C 14/20

(52) U.S. Cl. CPC C08L 85/02; C08J 5/00; C23C 14/24; B29C 45/0053; B29C 45/0001; B29K 2085/00; C08J 2385/02; C08J 2423/22; C08L 2205/035; B29C 2045/0079; B29K 2995/003; C23C 14/20

(57) ABSTRACT

A laminated molded article includes a molded product formed from a resin composition and a metal thin-film layer. The composition contains a polyphenylene ether resin (A) and an amorphous α-olefin copolymer (B). The resin (A) includes 95 to 99.95 mass % of a polyphenylene ether (i) and 0.05 to 5 mass % of a compound (ii) being at least one compound selected from the group consisting of: an organophosphorus compound having, in molecules thereof, a chemical structure represented by formula (I) or (II) (R in formula (II) is a trivalent saturated hydrocarbon group having a carbon number of 1 to 8 or a trivalent aromatic hydrocarbon group having a carbon number of 6 to 12); and a phosphonic acid, phosphonic acid ester, phosphinic acid, phosphinic acid ester, monocarboxylic acid, sulfonic acid, sulfinic acid, or carbonate other than the organophosphorus compound, relative to 100 mass %, in total, of components (i) and (ii).

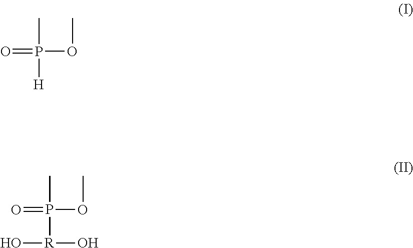

### TECHNICAL FIELD

This disclosure relates to a laminated molded article including a molded product formed from a polyphenylene ether resin composition and a metal thin-film layer.

### BACKGROUND

Polyphenylene ether resins are used widely as materials for home appliances, OA devices, office machines, information devices, automobiles, and so forth due to their various properties such as excellent mechanical properties, electrical properties, acid resistance, alkali resistance, and heat resistance, low specific gravity, low water absorbency, and good dimensional stability. In recent years, polyphenylene ether resin compositions have also been considered for use in automobile optical component applications, and applications in projectors, various lighting equipment, and the like.

In automobile optical component applications and applications in projectors, various lighting equipment, and the like, a laminated molded article that includes a molded product formed from a resin composition and a metal thin-film layer may be used. Since the laminated molded article requires processing treatment such as metal vapor deposition, a resin having excellent heat resistance such as a high-heat resistance polycarbonate or a glass reinforced material of polyethylene terephthalate (PET), which is advantageous in terms of cost despite a primer (undercoat) being required in metal vapor deposition, is used as the material of the molded product formed from a resin composition.

Polyphenylene ether resin compositions having excellent properties as described above are being investigated for use as the material of molded products in such laminated molded articles. For example, a technique has been disclosed in which a polyphenylene ether resin composition having excellent heat resistance and hydrolysis resistance is used (refer to PTL 1).

Moreover, in terms of techniques for increasing the surface glossiness of a laminated molded article including a molded product formed from a polyphenylene ether resin composition and a metal thin-film layer, a technique of performing aluminum vapor deposition directly onto a molded product obtained using a mold having a mirror surface finish (refer to PTL 2) and a technique of molding a molded product by setting the mold temperature in a range from approximately 40° C. lower than the heat deflection temperature to the heat deflection temperature (refer to PTL 3) have been disclosed.

Furthermore, a polyphenylene sulfide resin composition has been disclosed focusing on mold releasability of a molded product with the aim of improving metal surface appearance of a laminated molded article (refer to PTL 4).

Moreover, the use of an olefin resin in a resin composition forming a molded product on which metal vapor deposition is performed has been disclosed with the aim of improving metal surface appearance of a laminated molded article (refer to PTL 5); however, no disclosure is made in relation to close adhesion between the metal vapor deposited layer and the resin composition.

In production of a laminated molded article including a metal thin-film layer as described above, the surface of a molded product formed from a resin composition is normally subjected to processing treatment such as aluminum vapor deposition treatment to form the metal thin-film layer. From a viewpoint of quality of the laminated molded article, close adhesion between the metal thin-film layer and the molded product formed from the resin composition is vital, and there is also demand for close adhesion of the metal vapor deposition mirror surface to the resin composition even upon exposure to high temperature and high humidity conditions over a long period.

### CITATION LIST

### Patent Literature

PTL 1: JP H5-320495 A

PTL 2: JP H11-60935 A

PTL 3: JP H11-116793 A

PTL 4: JP 2004-35635 A

PTL 5: JP 2012-164577 A

### SUMMARY

### Technical Problem

However, with regards to the laminated molded articles disclosed in PTL 1 to 5, in a case in which a metal thin-film layer is formed by vapor deposition of a metal such as aluminum on the surface of a molded product formed from a resin composition (particularly in a case in which a polyphenylene ether resin is used), further improvement in terms of close adhesion between the metal thin-film layer and the molded product, and in terms of surface reflectance of the metal thin-film layer would be desirable.

Accordingly, an objective of this disclosure is to provide a laminated molded article having high surface reflectance and excellent close adhesion between a molded product formed from a polyphenylene ether resin composition and a metal thin-film layer.

### Solution to Problem

The inventors conducted diligent investigation to solve the problems set forth above. Through this investigation, the inventors discovered that through inclusion of a molded product formed from a polyphenylene ether resin composition that contains a specific compound in a specific amount and a metal thin-film layer, a laminated molded article having high surface reflectance and excellent close adhesion between the molded product and the metal thin-film layer can be obtained. The inventors completed the present disclosure based on this discovery.

Specifically, this disclosure provides the following.

[1] A laminated molded article comprising:

a molded product formed from a resin composition; and

a metal thin-film layer, wherein

the resin composition contains a polyphenylene ether resin (A) and an amorphous α-olefin copolymer (B), and

the polyphenylene ether resin (A) includes a polyphenylene ether (i) and a compound (ii) being at least one compound selected from the group consisting of: an organophosphorus compound having, in molecules thereof, a chemical structure represented by formula (I) or (II), shown below,

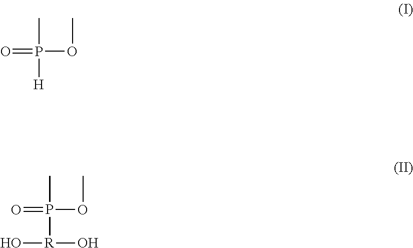

where R in formula (II) is a trivalent saturated hydrocarbon group having a carbon number of 1 to 8 or a trivalent aromatic hydrocarbon group having a carbon number of 6 to 12; and a phosphonic acid, phosphonic acid ester, phosphinic acid, phosphinic acid ester, monocarboxylic acid, sulfonic acid, sulfinic acid, or carbonate other than the organophosphorus compound in amounts of 95 mass % to 99.95 mass % of the component (i) and 0.05 mass % to 5 mass % of the component (ii) relative to 100 mass %, in total, of the components (i) and (ii).

[2] The laminated molded article according to the foregoing [1], wherein

the resin composition contains 0.1 mass % to 3 mass % of the amorphous α-olefin copolymer (B) relative to 100 mass % of the polyphenylene ether resin (A).

[3] The laminated molded article according to the foregoing [1] or [2], wherein

the resin composition contains 59 mass % to 98 mass % of the polyphenylene ether resin (A), 0 mass % to 30 mass % of a styrene resin (C), and 1 mass % to 35 mass % of an elastomer component (D) relative to 100 mass % of the resin composition.

[4] The laminated molded article according to any one of the foregoing [1] to [3], wherein

the polyphenylene ether (i) includes at least one structural unit selected from the group consisting of chemical formulae (1), (2), and (3), shown below,

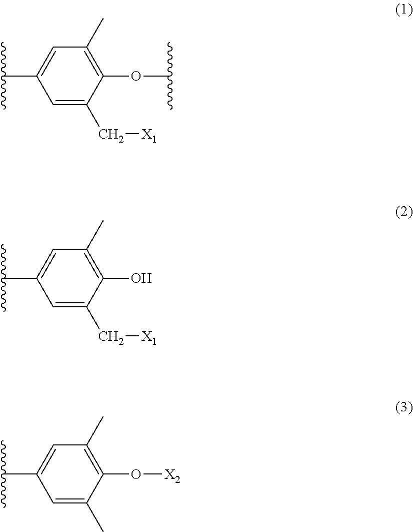

where X₁ in chemical formulae (1) and (2) is one group selected from

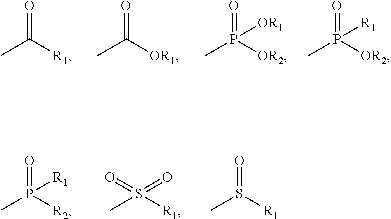

with R₁ and R₂ in X₁ each being, independently of one another, a substituent having a carbon number of 1 or more, and

X₂ in chemical formula (3) is one group selected from the group consisting of

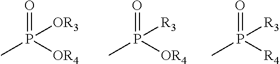

with R₃ and R₄ in X₂ each being, independently of one another, a group selected from the group consisting of a hydrogen atom, an alkyl group, an aryl group, an alkylamino group, and an arylamino group, where R₃ and R₄ may form a cyclic structure through bonding of respective carbon atoms included therein, and chemical formula (3) does not substantially include an unsaturated double bond other than an aromatic ring unsaturated double bond.

[5] The laminated molded article according to any one of the foregoing [1] to [4], wherein

the at least one structural unit selected from the group consisting of chemical formulae (1), (2), and (3) is contained in a ratio of 0.01 units to 10.0 units per 100 monomer units composing the polyphenylene ether (i).

[6] The laminated molded article according to any one of the foregoing [1] to [5], wherein

a ratio of a structural unit represented by chemical formula (1) relative to a structural unit represented by chemical formula (2) in the polyphenylene ether (i) is 0 mol % to 30 mol %.

[7] The laminated molded article according to any one of the foregoing [1] to [6], wherein

the polyphenylene ether (i) includes a structural unit represented by chemical formula (3) and either or both of a structural unit represented by chemical formula (1) and a structural unit represented by chemical formula (2).

[8] The laminated molded article according to any one of the foregoing [1] to [7], wherein

the polyphenylene ether (i) includes at least one structural unit selected from the group consisting of chemical formulae (4), (5), and (6), shown below,

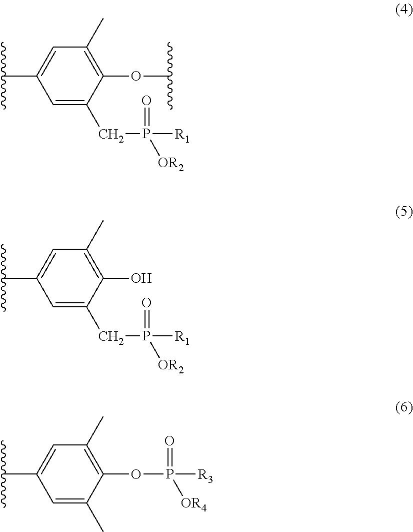

where R₁ and R₂ in chemical formulae (4) and (5) are each, independently of one another, a substituent having a carbon number of 1 or more, R₃ and R₄ in chemical formula (6) are each, independently of one another, a group selected from the group consisting of a hydrogen atom, an alkyl group, an aryl group, an alkylamino group, and an arylamino group, R₃ and R₄ may form a cyclic structure through bonding of respective carbon atoms included therein, and chemical formula (6) does not substantially include an unsaturated double bond other than an aromatic ring unsaturated double bond.

[9] The laminated molded article according to any one of the foregoing [1] to [8], wherein

the metal thin-film layer has a thickness of 12 nm or less.

[10] The laminated molded article according to any one of the foregoing [1] to [9], wherein

the metal thin-film layer is a vapor deposited film formed from aluminum.

### Advantageous Effect

According to this disclosure, it is possible to obtain a laminated molded article having high surface reflectance and excellent close adhesion between a molded product formed from a resin composition and a metal thin-film layer.

### DETAILED DESCRIPTION

The following provides a detailed description of an embodiment of this disclosure (hereinafter, referred to as the “present embodiment”). However, this disclosure is not limited to the following embodiment and may be implemented with various alterations that are within the essential scope thereof.

[Laminated Molded Article]

A laminated molded article according to an embodiment of the present disclosure includes a molded product formed from a resin composition and a metal thin-film layer. The molded product formed from the resin composition contains a polyphenylene ether resin (A) and an amorphous α-olefin copolymer (B). Through this configuration, it is possible to provide a laminated molded article having high surface reflectance, excellent close adhesion between a molded product and a metal thin-film layer, and excellent surface appearance. Moreover, it is possible to provide a laminated molded article that can maintain high surface reflectance, excellent close adhesion, and excellent surface appearance even after exposure to high temperature and high humidity conditions.

Although the thickness of the laminated molded article can be set as appropriate depending on the use thereof without any specific limitations, in a case in which the molded product is thick, the solidification rate in an inner part of the molded product is slow, sink marks may form in the molded product, and voids may arise in the inner part of the molded product, which may lead to poor surface smoothness of the molded product and poor external appearance of the laminated molded article. Accordingly, the laminated molded article preferably includes a thin molded product. Moreover, in applications in which weight-reduction is required, such as for automobile optical components, projectors, and various lighting equipment, the thickness of the laminated molded article may, for example, be 3 mm or less.

[[Molded Product]]

The molded product included in the laminated molded article of the present embodiment is formed from a resin composition that has been molded into a desired form.

The following describes the resin composition from which the molded product is formed.

[[[Resin Composition]]]

The resin composition forming the molded product contains a polyphenylene ether resin (A) and an amorphous α-olefin copolymer (B). The resin composition may optionally further contain a styrene resin (C), an elastomer component (D), an antioxidant (E), and other materials (F).

Although no specific limitations are placed on the content of components (A) to (F), the resin composition preferably contains 59 mass % to 98 mass % of component (A), 0 mass % to 30 mass % of component (C), and 1 mass % to 35 mass % of component (D) relative to 100 mass % of the resin composition. The resin composition more preferably contains 59 mass % to 98 mass % of component (A), 0 mass % to 30 mass % of component (C), and 1 mass % to 32 mass % of component (D) relative to 100 mass % of the resin composition, and even more preferably contains 62 mass % to 98 mass % of component (A), 0 mass % to 30 mass % of component (C), and 1 mass % to 32 mass % of component (D) relative to 100 mass % of the resin composition. When any of the ranges set forth above are satisfied, the laminated molded article can suitably be used as a metal thin-film layer-containing laminated molded article for an automobile component from a viewpoint of maintenance of high surface reflectance and excellent close adhesion after exposure to high temperature and high humidity conditions.

<Polyphenylene Ether Resin (A)>

The polyphenylene ether resin (A) includes a polyphenylene ether (i) and a compound (ii) being at least one compound selected from the group consisting of: an organophosphorus compound having, in molecules thereof, a chemical structure represented by the following formula (I) or (II) (R in formula (II) is a trivalent saturated hydrocarbon group having a carbon number of 1 to 8 or a trivalent aromatic hydrocarbon group having a carbon number of 6 to 12); and a phosphonic acid, phosphonic acid ester, phosphinic acid, phosphinic acid ester, monocarboxylic acid, sulfonic acid, sulfinic acid, or carbonate other than the organophosphorus compound in amounts of 95 mass % to 99.95 mass % of component (i) and 0.05 mass % to 5 mass % of component (ii) relative to 100 mass %, in total, of components (i) and (ii).

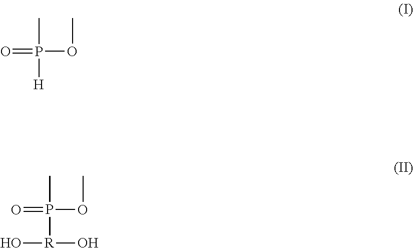

Although the content of the polyphenylene ether resin (A) is not specifically limited, in 100 mass % of the resin composition, the content of the polyphenylene ether resin (A) is preferably 59 mass % to 98 mass %, and more preferably 62 mass % to 98 mass %. A polyphenylene ether resin (A) content of 59 mass % or more is preferable from a viewpoint of maintaining high surface reflectance and excellent close adhesion after exposure to high temperature and high humidity conditions, whereas a polyphenylene ether resin (A) content of 98 mass % or less is preferable from a viewpoint of enhancing molding fluidity.

<<Polyphenylene Ether (i)>>

The polyphenylene ether (i) has the following formula (III) and/or (IV) as a repeating unit and is preferably a homopolymer or a copolymer in which constitutional units are formed from general formula (III) and/or (IV), or a modified product thereof.

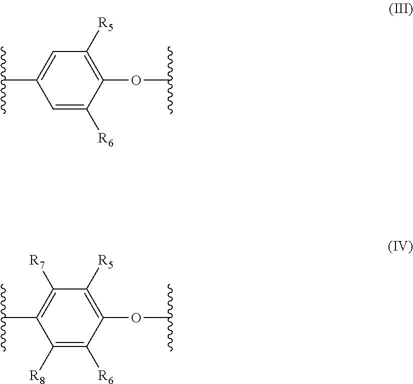

In chemical formulae (III) and (IV), R₅, R₆, R₇, and R_{g} represent, independently of one another, a hydrogen atom, an alkyl group having a carbon number of 1 to 4, an aryl group having a carbon number of 6 to 9, or a halogen atom, with the proviso that R₅ and R₆ do not both represent a hydrogen atom.

It should be noted that the number of repeating units of the preceding formulae (III) and (IV) is not specifically limited as it varies depending on the molecular weight distribution of the polyphenylene ether (i).

Examples of polyphenylene ether homopolymers that can be used include, but are not limited to, poly(2,6-dimethyl-1,4-phenylene) ether, poly(2-methyl-6-ethyl-1,4-phenylene) ether, poly(2,6-diethyl-1,4-phenylene) ether, poly(2-ethyl-6-n-propyl-1,4-phenylene) ether, poly(2,6-di-n-propyl-1,4-phenylene) ether, poly(2-methyl-6-n-butyl-1,4-phenylene) ether, poly(2-ethyl-6-isopropyl-1,4-phenylene) ether, poly(2-methyl-6-chloroethyl-1,4-phenylene) ether, poly(2-methyl-6-hydroxyethyl-1,4-phenylene) ether, and poly(2-methyl-6-chloroethyl-1,4-phenylene) ether. Of these polyphenylene ether homopolymers, poly(2,6-dimethyl-1,4-phenylene) ether is preferable from a viewpoint of ease of raw material acquisition and processability.

Examples of copolymers that can be used as the polyphenylene ether (i) include, but are not limited to, copolymers composed mainly of a polyphenylene ether structure such as a copolymer of 2,6-dimethylphenol and 2,3,6-trimethylphenol, a copolymer of 2,6-dimethylphenol and o-cresol, and a copolymer of 2,3,6-trimethylphenol and o-cresol. Of these copolymers, a copolymer of 2,6-dimethylphenol and 2,3,6-trimethylphenol is preferable from a viewpoint of ease of raw material acquisition and processability, and a copolymer of 90 mass % to 70 mass % of 2,6-dimethylphenol and 10 mass % to 30 mass % of 2,3,6-trimethylphenol is more preferable from a viewpoint of enhancing physical properties.

It is preferable that a structure in which R₅ and R₆ in chemical formula (III) are both methyl groups (and a structure derived therefrom as described further below) is included in at least part of the polyphenylene ether chain.

In the polyphenylene ether (i), the concentration of terminal OH groups is preferably 0.4 groups to 10.0 groups, and more preferably 0.5 groups to 1.8 groups per 100 monomer units composing the polyphenylene ether.

Note that the terminal OH group concentration of the PPE can be calculated through NMR measurement by, for example, measuring the PPE by ¹³C-NMR proton inverse gated decoupling (quantitative measurement) and calculating the spectral ratio of 1-position carbons (146.1 ppm) bonded to terminal OH groups relative to 1-position carbons (145.4 ppm, 151.4 ppm) in side chains to calculate the terminal OH group concentration (number of terminal OH groups per 100 monomer units composing the PPE).

The number average molecular weight (Mn) of the polyphenylene ether (i) is preferably 8,000 or more, and more preferably 14,000 or more, and is preferably 20,000 or less, and more preferably 19,000 or less. An excellent balance of heat resistance, fluidity, chemical resistance, and so forth can be obtained when the molecular weight is within any of the ranges set forth above.

The reduced viscosity of the polyphenylene ether (i) used in the present embodiment is preferably within a range of 0.25 dL/g to 0.55 dL/g. The reduced viscosity is more preferably within a range of 0.30 dL/g to 0.50 dL/g. A polyphenylene ether reduced viscosity of at least 0.25 dL/g and not more than 0.55 dL/g is preferable from a viewpoint of maintaining high surface reflectance and excellent close adhesion after exposure to high temperature and high humidity conditions.

In the present embodiment, the reduced viscosity is a value obtained by using an Ubbelohde-type viscometer to measure a 0.5 g/dL solution at 30° C. using chloroform solvent.

The polyphenylene ether (i) can normally be acquired as a powder and the particle size of the powder is preferably an average particle diameter of 1 μm to 1,000 μm, more preferably 10 μm to 700 μm, and particularly preferably 100 μm to 500 μm. An average particle diameter of 1 μm or more is preferable from a viewpoint of ease of handling in processing, whereas an average particle diameter of 1,000 μm or less is preferable for inhibiting the occurrence of unmelted material in melt-kneading.

The ratio of the weight average molecular weight (Mw) and the number average molecular weight (Mn) (Mw/Mn value) of the polyphenylene ether (i) used in the present embodiment, prior to heated processing by extrusion or the like (i.e., as a property of the polymer powder), is preferably 1.2 to 3.0, more preferably 1.5 to 2.5, and even more preferably 1.8 to 2.3. An Mw/Mn value of 1.2 or more is preferable from a viewpoint of molding processability of the resin composition, whereas an Mw/Mn value of 3.0 or less is preferable from a viewpoint of mechanical properties of the resin composition, and particularly from a viewpoint of retaining tensile strength. The weight average molecular weight Mw and the number average molecular weight Mn can be obtained as molecular weights in terms of polystyrene through measurement by GPC (gel permeation chromatography).

The content of the polyphenylene ether (i) used in the present embodiment in 100 mass %, in total, of components (i) and (ii) is within a range of 95 mass % to 99.95 mass %, and is preferably within a range of 95 mass % to 99.9 mass %, and more preferably within a range of 96 mass % to 99.9 mass %. The polyphenylene ether (i) content is set as 95 mass % or more from a viewpoint of retaining adequate molded product external appearance and is preferably 99.95 mass % or less from a viewpoint of retaining the properties required for the applications described herein and sufficiently enhancing the laminated molded article surface at which the metal thin-film layer is provided.

The polyphenylene ether (i) may be one type used individually, or may be two or more types used in combination.

The polyphenylene ether (i) preferably includes at least one structural unit selected from the group consisting of the following chemical formulae (1), (2), and (3).

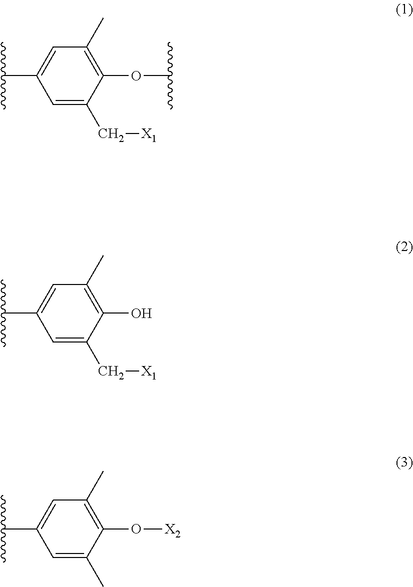

X₁ in chemical formulae (1) and (2) is one group selected from

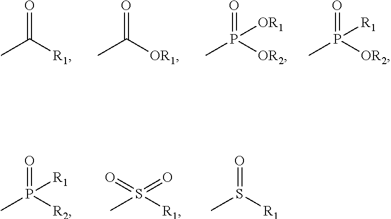

where R₁ and R₂ in X₁ are each, independently of one another, a substituent having a carbon number of 1 or more.

X₂ in chemical formula (3) is one group selected from

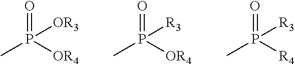

where R₃ and R₄ in X₂ are each, independently of one another, a group selected from the group consisting of a hydrogen atom, an alkyl group, an aryl group, an alkylamino group, and an arylamino group. Moreover, R₃ and R₄ may form a cyclic structure through bonding of respective carbon atoms included therein. Note that formula (3) does not substantially include an unsaturated double bond other than an aromatic ring unsaturated double bond. More specifically, formula (3) does not substantially include a carbon-carbon double bond other than an aromatic ring double bond.

A case in which X₁ in formulae (1) and (2) is one group selected from

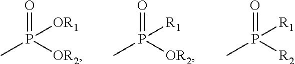

is more preferable.

The polyphenylene ether (i) is more preferably a polyphenylene ether that includes a structural unit represented by formula (1) and/or a structural unit represented by formula (2), and also includes a structural unit represented by formula (3).

The structure of R₁ and R₂ in X₁ of formulae (1) and (2) is preferably a substituent that does not include a reactive functional group. If reactive substituents are present, these reactive substituents may undergo a crosslinking reaction when the resin composition is exposed to a high temperature over a long period, which may cause deterioration of the external appearance of an aluminum vapor deposition mirror surface of the molded product. Examples of reactive substituents include a hydroxy group, an alkoxy group, an amino group, a vinyl group, and a carbonyl group. R₁ and R₂ in X₁ may have a structure in which R₁ and R₂ are linked, and may have a structure including a nitrogen atom and/or an oxygen atom.

R₁ and R₂ in X₁ of formulae (1) and (2) may, for example, be a chain or cyclic alkyl group having a carbon number of 1 to 30, or an aryl group. Specific examples include a methyl group, an ethyl group, an n-propyl group, an i-propyl group, an n-butyl group, a t-butyl group, a hexyl group, a cyclohexyl group, an octyl group, a decyl group, a dodecyl group, a hexadecyl group, an octadecyl group, a phenyl group, a tolyl group, and a naphthyl group.

The structure of R₃ and R₄ in X₂ of formula (3) is preferably an alkyl group, aryl group, alkylamino group, or arylamino group that does not include an unsaturated double bond other than an aromatic ring unsaturated double bond, and may be a structure in which the two substituents are linked or a structure including a nitrogen atom and/or an oxygen atom.

An alkyl group represented by R₃ or R₄ in X₂ of formula (3) may, for example, be an alkyl group having a carbon number of 1 to 30. Specific examples include a methyl group, an ethyl group, an n-propyl group, an i-propyl group, an n-butyl group, a t-butyl group, a hexyl group, a cyclohexyl group, an octyl group, a decyl group, a dodecyl group, a hexadecyl group, and an octadecyl group.

An aryl group represented by R₃ or R₄ in X₂ of formula (3) may, for example, be an aryl group having a carbon number of 6 to 30. Specific examples include a phenyl group, a tolyl group, a dimethylphenyl group, a trimethylphenyl group, a naphthyl group, and a trityl group.

The alkyl group in an alkylamino group represented by R₃ or R₄ in X₂ of formula (3) may, for example, be an alkyl group having a carbon number of 1 to 30. Specific examples include a methyl group, an ethyl group, an n-propyl group, an i-propyl group, a butyl group, a hexyl group, a cyclohexyl group, an octyl group, a decyl group, a dodecyl group, a hexadecyl group, and an octadecyl group. Moreover, examples of the alkylamino group include a methylamino group, a dimethylamino group, an ethylamino group, a diethylamino group, an isopropylamino group, a diisopropylamino group, a butylamino group, a dibutylamino group, an octylamino group, and a dioctylamino group.

The aryl group in an arylamino group represented by R₃ or R₄ in X₂ of formula (3) may, for example, be any of the previously described aryl groups. Specific examples of the arylamino group include a phenylamino group, a diphenylamino group, a tolylamino group, a ditolylamino group, a dimethylphenylamino group, a trimethylphenylamino group, a naphthylamino group, and a tritylamino group.

In the case of a polyphenylene ether (i) that includes a structural unit represented by formula (3), it is preferable that end structural units represented by formula (3) do not substantially include unsaturated double bonds other than aromatic ring unsaturated double bonds (i.e., do not substantially include carbon-carbon double bonds other than aromatic ring double bonds). Among such polyphenylene ethers, those that do not substantially include unsaturated double bonds other than aromatic ring unsaturated double bonds in the polyphenylene ether chain are preferable. An unsaturated double bond is a structure that has high reactivity upon heating. Consequently, upon expose to a high temperature over a long period, the unsaturated double bond may cause an intermolecular or intramolecular crosslinking reaction, leading to a reduction in heat aging-resistance characteristics.

The number of unsaturated bonds other than those of aromatic rings can be measured from a doublet peak that differs from precursor polyphenylene ether and appears at 3.5 ppm to 5.5 ppm in ¹H-NMR measurement under conditions described in the subsequent EXAMPLES section. Note that in a case in which the number of unsaturated double bonds other than those of aromatic rings is 0.01 or more per 100 monomer units composing the polyphenylene ether (i), the unsaturated double bonds can be detected by ¹H-NMR measurement under the conditions described in the subsequent EXAMPLES section.

Herein, “terminal structural units represented by formula (3) do not substantially include unsaturated double bonds other than aromatic ring unsaturated double bonds” means that a double peak differing from precursor polyphenylene ether is not detected at 3.5 ppm to 5.5 ppm in ¹H-NMR performed under the measurement conditions described in the subsequent EXAMPLES section.

In the chain of the polyphenylene ether (i), the content of structural units selected from the group consisting of chemical formulae (1), (2), and (3) is preferably 0.01 units to 10.0 units per 100 monomer units composing the polyphenylene ether (i).

Moreover, in the chain of the polyphenylene ether (i), the content of structural units represented by chemical formula (1) and/or (2) is preferably within a range of 0.05 units to 10 units, more preferably within a range of 0.1 units to 3 units, and even more preferably within a range of 0.1 units to 1.0 units per 100 monomer units composing the polyphenylene ether. Through inclusion of at least 0.05 structural units and not more than 10 structural units represented by chemical formula (1) and/or (2) per 100 units, high surface reflectance can be maintained even after the laminated molded article is exposed to high temperature and high humidity conditions over a long period.

From a viewpoint of maintaining high surface reflectance after the laminated molded article is exposed to high temperature and high humidity conditions over a long period, the ratio of structural units represented by formula (1) relative to structural units represented by formula (2) ([moles of structural units represented by formula (1)/moles of structural units represented by formula (2)]×100) is preferably 0 mol % to 30 mol %, and more preferably 0 mol % to 28 mol %.

The content of structural units represented by chemical formula (3) in the polyphenylene ether (i) is preferably within a range of 0.01 units to 10 units, and more preferably within a range of 0.01 units to 5 units per 100 monomer units composing the polyphenylene ether. Through inclusion of at least 0.01 structural units and not more than 10 structural units represented by chemical formula (3), good surface reflectance can be maintained even after the laminated molded article is exposed to high temperature and high humidity conditions over a long period, and, in particular, inclusion of 5 or fewer structural units represented by chemical formula (3) is more preferable.

The number of structural units represented by formula (3) per 100 monomer units composing the polyphenylene ether (i) is even more preferably within a range of 0.01 units to 3.0 units, and particularly preferably within a range of 0.01 units to 1.0 units.

The following describes the action and effects of a polyphenylene ether (i) that includes at least one structural unit selected from chemical formulae (1), (2), and (3).

In the case of a conventional polyphenylene ether, methyl groups present in terminal units (hereinafter, also referred to as “terminal methyl groups”), methyl groups present in intermediate units (hereinafter, also referred to as “side chain methyl groups”), and hydroxy groups present in terminal units (also referred to as “terminal hydroxy groups” in the present specification) may cause an oxidative crosslinking reaction when the polyphenylene ether is exposed to a high temperature over a long period. The inventors focused on oxidative crosslinking reaction of terminal methyl groups, side chain methyl groups, and the like, and investigated whether it is possible to inhibit this oxidative crosslinking reaction such as to further inhibit the occurrence of depressions in the surface of a molded product on which a metal thin-film layer is formed, and to further inhibit deterioration of mirror surface appearance of the metal thin-film layer due to progression of these depressions. The inventors found that radicals tend to be generated relatively easily at terminal methyl groups, side chain methyl groups, and terminal hydroxy groups, and that the generated radicals may act as a cause of oxidative crosslinking. It is presumed that in the case of a polyphenylene ether (i) that includes at least one structural unit selected from chemical formulae (1), (2), and (3), an oxidization site (terminal methyl group, side chain methyl group, or terminal hydroxy group) is blocked by being substituted with a specific molecule, which inhibits a crosslinking reaction at this oxidation site (terminal methyl group, side chain methyl group, or terminal hydroxy group), and thereby inhibits formation of depressions in the molded product formed from the resin composition and improves close adhesion of the molded product to the metal thin-film layer.

From a viewpoint of enabling maintenance of high surface reflectance and excellent close adhesion even when the laminated molded article is exposed to a high temperature and high humidity environment over a long period, chemical formulae (1), (2), and (3) are preferably chemical formula (4), (5), and (6), respectively. In other words, the polyphenylene ether (i) preferably includes at least one structural unit selected from the group consisting of chemical formulae (4), (5), and (6).

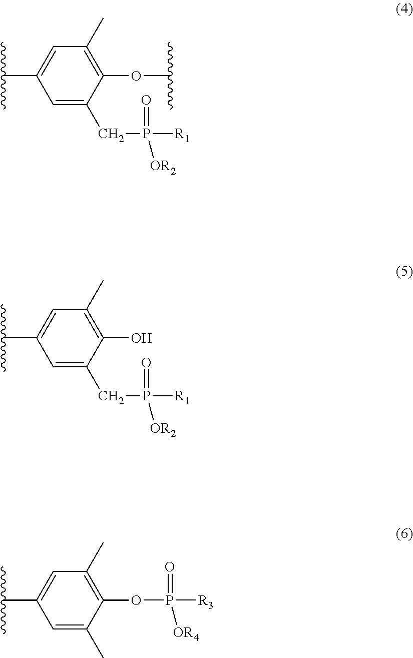

Note that R₁ and R₂ in chemical formulae (4) and (5) are the same as R₁ and R₂ in X₁ of chemical formulae (1) and (2), and R₃ and R₄ in chemical formula (6) are the same as R₃ and R₄ in X₂ of chemical formula (3).

—Method of Synthesis of Polyphenylene Ether (i)—

Normal polymer powders of polyphenylene ethers synthesized by already commonly known polymerization methods can be widely used as the polyphenylene ether (i).

Of such polyphenylene ethers, a polyphenylene ether (i) that includes at least one structural unit selected from the group consisting of chemical formulae (1) and (2) is preferably synthesized by using a polyphenylene ether that has a substituent other than X₁ of chemical formulae (1) and (2) on the methylene group in chemical formulae (1) and (2) of the polyphenylene ether (i) as a precursor (hereinafter, also referred to as a “precursor polyphenylene ether”), and reacting this precursor polyphenylene ether with a subsequently described reactive compound to synthesize the polyphenylene ether (i) including at least one structural unit selected from the group consisting of chemical formulae (1) and (2). According to this method, the polyphenylene ether (i) including at least one structural unit selected from the group consisting of chemical formulae (1) and (2) is synthesized from the precursor polyphenylene ether, and thus can be obtained more efficiently than when synthesized from a polyphenylene ether (hereinafter, also referred to as an “unsubstituted polyphenylene ether”) for which the X₁ part in chemical formula (1) and/or (2) of the polyphenylene ether (i) is hydrogen. The reaction of the precursor polyphenylene ether (also referred to as the “precursor PPE”) and the reactive compound is preferably performed through heat.

A polyphenylene ether (i) that includes a structural unit of chemical formula (3) is preferably obtained in the same way as described above by causing a precursor polyphenylene ether and a subsequently described reactive compound to react through heat. The polyphenylene ether (i) including a structural unit of chemical formula (3) is preferably obtained by reacting the reactive compound with a polyphenylene ether terminal hydroxy group.

The precursor polyphenylene ether is preferably a polyphenylene ether that includes, in an unsubstituted polyphenylene ether chain, terminal group and side chain group-containing structural units represented by the following chemical formulae (7) and (8). Through inclusion of a structural unit of the following chemical formula (7) and/or a structural unit of the following chemical formula (8) in the precursor polyphenylene ether, a polyphenylene ether (i) that includes at least one structural unit selected from chemical formulae (1) and (2) can be obtained with sufficient efficiency (specifically, in production of the polyphenylene ether (i), by carrying out production via the precursor polyphenylene ether, the CH₂—Y part of the structures of chemical formulae (7) and (8) is selectively cleaved to undergo a substitution reaction with a subsequently described reactive compound, and thereby obtain a polyphenylene ether (i) that includes at least one structural unit selected from chemical formulae (1) and (2) with sufficient efficiency). Moreover, since the precursor polyphenylene ether can be easily synthesized from an unsubstituted polyphenylene ether, a polyphenylene ether (i) including at least one structural unit selected from chemical formula (1) and (2) can be efficiently synthesized via the precursor polyphenylene ether.

The total content of such structural units in the polyphenylene ether chain of the precursor polyphenylene ether is preferably 0.05 units to 10 units, and more preferably 0.1 units to 10 units per 100 monomer units composing the polyphenylene ether.

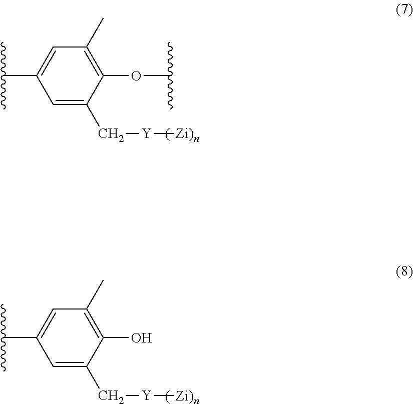

(In chemical formulae (7) and (8), Y represents a N atom or an O atom, and Zi represents a cyclic or chain (linear or branched) saturated or unsaturated hydrocarbon group having a carbon number of 1 to 20. Moreover, in chemical formulae (7) and (8), i and n each represent an integer of 1 to 2, where Z1 and Z2 may be the same or different, and may be bonded to one another to form a cyclic structure in combination with Y bonded thereto.)

The method by which the precursor polyphenylene ether including a structural unit of chemical formula (7) and/or (8) is produced is not specifically limited and examples thereof include a method in which a compound (a1) such as an amine, an alcohol, or morpholine is added and reacted in the polymerization reaction of a polyphenylene ether and a method in which an unsubstituted polyphenylene ether that has been polymerized is stirred at 20° C. to 60° C., for example, and preferably at 40° C., in a solvent in which polyphenylene ether dissolves, such as toluene, while adding and reacting the compound (a1).

Although the compound (a1) is not specifically limited, specific examples that can be used include primary amines such as n-propylamine, iso-propylamine, n-butylamine, iso-butylamine, sec-butylamine, n-hexylamine, n-octylamine, 2-ethylhexylamine, cyclohexylamine, laurylamine, and benzylamine; secondary amines such as diethylamine, di-n-propylamine, di-n-butylamine, di-iso-butylamine, di-n-octylamine, piperidine, and 2-pipecoline; alcohols such as methanol, ethanol, n-propanol, iso-propanol, n-butanol, iso-butanol, and sec-butanol; and morpholine.

Examples of methods by which a polyphenylene ether (i) including at least one structural unit selected from chemical formula (1) to (3) can be obtained include, but are not specifically limited to, a method in which a subsequently described reactive compound is added in polymerization of a polyphenylene ether, and polyphenylene ether polymerization is carried out, a method in which a monomer substituted with a subsequently described reactive compound is added in a small amount in polymerization of a polyphenylene ether, and polyphenylene ether polymerization is carried out, and a method in which an unsubstituted polyphenylene ether and a reactive compound are melt-kneaded and reacted. More specifically, examples of methods that can be adopted include a method in which the compound (a1) is added and reacted in polymerization of a polyphenylene ether, and then a subsequently described reactive compound is reacted, a method in which 2,6-dimethylphenol substituted with the compound (a1) is added and reacted in a small amount in polymerization of a polyphenylene ether, and then melt-kneading is performed with a reactive compound to cause a reaction therewith, and a method in which a precursor polyphenylene ether is obtained, and then the precursor polyphenylene ether and a reactive compound are melt-kneaded and reacted (i.e., the precursor polyphenylene ether and the reactive compound may, for example, be melt-kneaded in melt-kneading for producing the resin composition using the precursor polyphenylene ether). The melt-kneading conditions may be the same as melt-kneading conditions in production of the resin composition.

—Reactive Compound—

Examples of reactive compounds that can be used to obtain a polyphenylene ether (i) that includes at least one structural unit selected from chemical formulae (1) to (3) include, but are not limited to, phosphonic acids, phosphonic acid esters, phosphinic acids, phosphinic acid esters, monocarboxylic acids, sulfonic acids, sulfinic acids, and carbonates.

Examples of phosphonic acids that can be used as the reactive compound include phosphonic acid (phosphorus acid), methylphosphonic acid, ethylphosphonic acid, vinylphosphonic acid, decylphosphonic acid, phenylphosphonic acid, benzylphosphonic acid, aminomethylphosphonic acid, methylenediphosphonic acid, 1-hydroxyethane-1,1-diphosphonic acid, 4-methoxyphenylphosphonic acid, and propylphosphonic anhydride.

Examples of phosphonic acid esters that can be used as the reactive compound include dimethyl phosphonate, diethyl phosphonate, bis(2-ethylhexyl) phosphonate, dioctyl phosphonate, dilauryl phosphonate, dioleyl phosphonate, diphenyl phosphonate, dibenzyl phosphonate, dimethyl methylphosphonate, diphenyl methylphosphonate, dioctyl methylphosphonate, diethyl ethylphosphonate, dioctyl ethylphosphonate, diethyl benzylphosphonate, dimethyl phenylphosphonate, diethyl phenylphosphonate, dipropyl phenylphosphonate, dioctyl phenylphosphonate, diethyl (methoxymethyl)phosphonate, dioctyl (methoxymethyl)phosphonate, diethyl vinylphosphonate, diethyl vinylphosphonate, diethyl hydroxymethylphosphonate, diethyl hydroxymethylphosphonate, dimethyl (2-hydroxyethyl)phosphonate, dioctyl (methoxymethyl)phosphonate, diethyl p-methylbenzylphosphonate, dioctyl p-methylbenzylphosphonate, diethyl phosphonoacetate, triethyl phosphonoacetate, tert-butyl diethylphosphonoacetate, di octyl di ethylphosphonate, diethyl (4-chlorobenzyl)phosphonate, dioctyl (4-chlorobenzyl)phosphonate, diethyl cyanophosphonate, diethyl cyanomethylphosphonate, di octyl cyanophosphonate, diethyl 3,5-di-tert-butyl-4-hydroxybenzylphosphonate, dioctyl 3,5-di-tert-butyl-4-hydroxybenzylphosphonate, and diethyl (methylthiomethyl)phosphonate.

Examples of phosphinic acids that can be used as the reactive compound include dimethylphosphinic acid, ethylmethylphosphinic acid, diethylphosphinic acid, methyl-n-propylphosphinic acid, diphenylphosphinic acid, dioleylphosphinic acid, 9,10-dihydro-9-oxa-10-phosphaphenanthrene-10-oxide, and derivatives thereof.

Examples of phosphinic acid esters that can be used as the reactive compound include methyl dimethylphosphinate, ethyl dimethylphosphinate, n-butyl dimethylphosphinate, cyclohexyl dimethylphosphinate, vinyl dimethylphosphinate, phenyl dimethylphosphinate, methyl ethylmethylphosphinate, ethyl ethylmethylphosphinate, n-butyl ethylmethylphosphinate, cyclohexyl ethylmethylphosphinate, vinyl ethylmethylphosphinate, phenyl ethylmethylphosphinate, methyl diethylphosphinate, ethyl diethylphosphinate, n-butyl diethylphosphinate, cyclohexyl diethylphosphinate, vinyl diethylphosphinate, phenyl diethylphosphinate, methyl diphenylphosphinate, ethyl diphenylphosphinate, n-butyl diphenylphosphinate, cyclohexyl diphenylphosphinate, vinyl diphenylphosphinate, phenyl diphenylphosphinate, methyl methyl-n-propylphosphinate, ethyl methyl-n-propylphosphinate, n-butyl methyl-n-propylphosphinate, cyclohexyl methyl-n-propylphosphinate, vinyl methyl-n-propylphosphinate, phenyl methyl-n-propylphosphinate, methyl dioleylphosphinate, ethyl dioleylphosphinate, n-butyl dioleylphosphinate, cyclohexyl dioleylphosphinate, vinyl dioleylphosphinate, and phenyl dioleylphosphinate.

Examples of monocarboxylic acids that can be used as the reactive compound include monocarboxylic acids such as formic acid, acetic acid, propionic acid, butyric acid, hexanoic acid, heptanoic acid, octanoic acid, nonanoic acid, decanoic acid, dodecanoic acid, tetradecanoic acid, octadecanoic acid, docosanoic acid, hexacosanoic acid, octadecenoic acid, docosenoic acid, and isooctadecanoic acid; alicyclic monocarboxylic acids such as cyclohexane carboxylic acid; aromatic monocarboxylic acids such as benzoic acid and methylbenzene carboxylic acid; hydroxy aliphatic monocarboxylic acids such as hydroxypropionic acid, hydroxyoctadecanoic acid, and hydroxyoctadecenoic acid; and sulfur-containing aliphatic monocarboxylic acids such as alkylthiopropionic acids.

Examples of sulfonic acids that can be used as the reactive compound include alkyl sulfonic acids, benzenesulfonic acid, naphthalenesulfonic acid, anthraquinonesulfonic acid, camphorsulfonic acid, and derivatives thereof. These sulfonic acids may be monosulfonic acids, disulfonic acids, or trisulfonic acids. Examples of derivatives of alkyl sulfonic acids include methanesulfonyl chloride. Examples of derivatives of benzenesulfonic acid include phenolsulfonic acid, styrenesulfonic acid, toluenesulfonic acid, and dodecylbenzenesulfonic acid. Examples of derivatives of naphthalenesulfonic acid include 1-naphthalenesulfonic acid, 2-naphthalenesulfonic acid, 1,3-naphthalenedisulfonic acid, 1,3,6-naphthalenetrisulfonic acid, and 6-ethyl-1-naphthalenesulfonic acid. Examples of derivatives of anthraquinonesulfonic acid include anthraquinone-1-sulfonic acid, anthraquinone-2-sulfonic acid, anthraquinone-2,6-disulfonic acid, and 2-methylanthraquinone-6-sulfonic acid.

Examples of sulfinic acids that can be used as the reactive compound include alkanesulfinic acids such as ethanesulfinic acid, propanesulfinic acid, hexanesulfinic acid, octanesulfinic acid, decanesulfinic acid, and dodecanesulfinic acid; alicyclic sulfinic acids such as cyclohexanesulfinic acid and cycloctanesulfinic acid; and aromatic sulfinic acids such as benzenesulfinic acid, o-toluenesulfinic acid, p-toluenesulfinic acid, ethylbenzenesulfinic acid, decylbenzenesulfinic acid, dodecylbenzenesulfinic acid, chlorobenzenesulfinic acid, and naphthalenesulfinic acid.

Examples of carbonates include dimethyl carbonate, diethyl carbonate, diisopropyl carbonate, dibutyl carbonate, dihexyl carbonate, dioctyl carbonate, diphenyl carbonate, methyl ethyl carbonate, methyl phenyl carbonate, ethyl phenyl carbonate, butyl phenyl carbonate, and ditolyl carbonate.

Phosphorus-containing compounds are preferable as the reactive compound from a viewpoint of reactivity. Specifically, diphenyl phosphonate, dioleyl phosphonate, dioctyl phosphonate, diphenylphosphinic acid, dioleylphosphinic acid, and the like are preferable, and 9,10-dihydro-9-oxa-10-phosphaphenanthrene-10-oxide is more preferable. A polyphenylene ether including at least one structural unit selected from chemical formulae (1) to (3) that is obtained using 9,10-dihydro-9-oxa-10-phosphaphenanthrene-10-oxide enables maintenance of good surface appearance and excellent close adhesion even after the laminated molded article is exposed to high temperature and high humidity conditions over a long period.

<<Compound (ii)>>

The compound (ii) is at least one compound selected from the group consisting of: an organophosphorus compound having, in molecules thereof, a chemical structure represented by formula (I) or (II) (R in formula (II) is a trivalent saturated hydrocarbon group having a carbon number of 1 to 8 or a trivalent aromatic hydrocarbon group having a carbon number of 6 to 12); and a phosphonic acid, phosphonic acid ester, phosphinic acid, phosphinic acid ester, monocarboxylic acid, sulfonic acid, sulfinic acid, or carbonate other than the organophosphorus compound. Examples of phosphonic acids, phosphonic acid esters, phosphinic acids, phosphinic acid esters, monocarboxylic acids, sulfonic acids, sulfinic acids, and carbonates other than the organophosphorus compound that can be used include the same phosphonic acids, phosphonic acid esters, phosphinic acids, phosphinic acid esters, monocarboxylic acids, sulfonic acids, sulfinic acids, and carbonates as described for the foregoing reactive compound.

From a viewpoint of achieving the objectives of the present application through sufficient performance expression, it is preferable to use an organophosphorus compound as the compound (ii) used in the present embodiment, and more preferable to use an organophosphorus compound having a reactive group of the following formula (1) or (2) in molecules thereof.

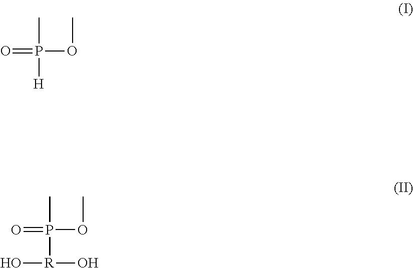

R in formula (II) is a trivalent saturated hydrocarbon group having a carbon number of 1 to 8 or a trivalent aromatic hydrocarbon group having a carbon number of 6 to 12.

Moreover, from a viewpoint of improving close adhesion between the metal thin-film layer and the molded product formed from the resin composition and a viewpoint of more favorably enhancing the surface appearance of the metal thin-film layer of the laminated molded article after exposure to a high temperature over a long period, it is preferable to use 9,10-dihydro-9-oxa-10-phosphaphenanthrene-10-oxide, a derivative thereof, or dioctyl phosphonate as an organophosphorus compound having the chemical structure of formula (I) or (II) in molecules thereof that is used in the present embodiment.

Examples of derivatives of 9,10-dihydro-9-oxa-10-phosphaphenanthrene-10-oxide include 10-(2,5-dihydroxyphenyl)-9,10-dihydro-9-oxa-10-phosphaphenanthrene-10-oxide and bis(2-hydroxyethyl)2-(10H-9-oxa-10-phospha-10-phenanthryl methyl)succinate P-oxide.

Of these examples, 9,10-dihydro-9-oxa-10-phosphaphenanthrene-10-oxide is more preferable from a viewpoint of sufficient close adhesion with the metal thin-film layer.

The content of component (ii) used in the present embodiment in 100 mass %, in total, of components (i) and (ii) is within a range of 0.05 mass % to 5 mass %, preferably within a range of 0.1 mass % to 5 mass %, and more preferably within a range of 0.1 mass % to 4 mass %. By setting the content of component (ii) as 5 mass % or less, good surface reflectance can be maintained even after the laminated molded article is exposed to high temperature and high humidity conditions over a long period. Moreover, by setting the content of component (ii) as 0.05 mass % or more, good surface reflectance can be obtained in the metal thin-film layer of the laminated molded article.

In production of the resin composition of the present embodiment, components (i) and (ii) may, in advance, be blended and then melt-kneaded using an extruder to extrude pellets that are used as a raw material with an objective of increasing the reaction rate of components (i) and (ii) contained in the polyphenylene ether resin (A). In terms of the blending ratio (mass ratio) of components (i) and (ii) in this pre-blending, the ratio of component (ii) in 100 mass % of the blended product of components (i) and (ii) is preferably within a range of 0.05 mass % to 10 mass %, more preferably within a range of 0.1 mass % to 5 mass %, and even more preferably within a range of 0.3 mass % to 3 mass %. Component (ii) is preferably blended in a ratio of 0.05 mass % or more from viewpoint of sufficiently enhancing performance and is preferably blended in a ratio of 10 mass % or less from a viewpoint of retaining stability in extrusion processing.

Although no specific limitations are placed on the melt-kneading conditions in a situation in which components (i) and (ii) are blended in advance and melt-kneaded by an extruder, it is appropriate to use a twin screw extruder having a screw diameter of 25 mm to 90 mm from a viewpoint of stably obtaining a large quantity of a resin composition that can sufficiently exhibit the effects desired in the present embodiment. As one example, in a case in which a TEM58SS twin screw extruder (produced by Toshiba Machine Co., Ltd.; number of barrels: 13; screw diameter: 58 mm; L/D=53; screw pattern including 2 kneading discs L, 14 kneading discs R, and 2 kneading discs N) is used, melt-kneading may be carried out under conditions of a cylinder temperature of 270° C. to 330° C., a screw rotation speed of 150 rpm to 700 rpm, an extrusion rate of 150 kg/h to 600 kg/h, and a vent degree of vacuum of 11.0 kPa to 1.0 kPa.

The temperature of extruded resin is preferably within a range of 250° C. to 380° C. The extruded resin temperature is more preferably within a range of 270° C. to 360° C., and even more preferably within a range of 300° C. to 350° C. An extruded resin temperature of 250° C. or higher is preferable from a viewpoint of sufficient reactivity and extrudability, whereas an extruded resin temperature of 380° C. or lower is preferable from a viewpoint of sufficient extrudability and retention of mechanical properties.

In a situation in which melt-kneading is performed using a large-scale (screw diameter: 40 mm to 90 mm) twin screw extruder, the oxygen concentration from inside of a raw material storage hopper to inside of a chute of a raw material feeding inlet is preferably set as 15 vol. % or less, more preferably 8 vol. % or less, and even more preferably 1 vol. % or less. By setting the oxygen concentration as 15 vol. % or less, it is possible to prevent gel and carbides that may be generated from the polyphenylene ether (i) in extrusion becoming mixed into the pellets, and it is possible to improve the surface appearance of the molded product and the surface reflectance of the laminated molded article.

Note that adjustment of the oxygen concentration can be performed by, after sufficiently purging the inside of the raw material storage hopper with nitrogen and tightly sealing a feed line from the raw material storage hopper to the raw material feeding inlet of the extruder such that air does not enter or exit the feed line, adjusting the nitrogen feed rate and the aperture of a gas vent.

<Amorphous α-Olefin Copolymer (B)>

The amorphous α-olefin copolymer (B) contained in the resin composition of the present embodiment is a copolymer having two or more different α-olefin monomers as main components. Specific examples of the amorphous α-olefin copolymer (B) include an ethylene-propylene copolymer, an ethylene-butene copolymer, an ethylene-octene copolymer, a propylene-butene copolymer, a propylene-hexene copolymer, a propylene-ethylene-butene copolymer, and a propylene-ethylene-hexene copolymer. An ethylene-propylene copolymer and an ethylene-butene copolymer are preferable. The mode of polymerization of the copolymer is not specifically limited and may be random polymerization or block polymerization.

The melt flow rate (MFR) of the amorphous α-olefin copolymer (B) is preferably 0.1 g/10 minutes to 50 g/10 minutes, and more preferably 0.2 g/10 minutes to 30 g/10 minutes. The melt flow rate is measured under conditions of 190° C. and 2.16 kgf by a measurement method in accordance with ASTM standard D1238.

Component (B) is preferably a copolymer for which a clear melting point peak (Tm) is not observed in DSC (differential scanning calorimetry) performed in accordance with ASTM-D2117.

The amorphous α-olefin copolymer (B) may be further copolymerized with components other than α-olefins to the extent that the performance thereof is not affected.

The ratio of component (B) in the resin composition of the present embodiment relative to 100 mass % of component (A) is preferably 0.1 mass % to 3 mass %. The range set forth above is preferable from a viewpoint of enabling excellent close adhesion between the metal thin-film layer and the molded product formed from the resin composition, and also enabling excellent close adhesion after aging in a high temperature and high humidity environment. The ratio of component (B) relative to 100 mass % of component (A) is more preferably 0.1 mass % to 2.5 mass %, and even more preferably 0.2 mass % to 2.3 mass %.

<Styrene Resin (C)>

A styrene resin (C) may be compounded in the resin composition of the present embodiment with the aim of adjusting heat resistance and molding fluidity. The styrene resin (C) is not specifically limited and may be any commonly known styrene resin. Examples include a homopolymer of a styrene compound and a polymer obtained through polymerization of a styrene compound and a compound that is copolymerizable therewith in the presence or absence of a rubbery polymer.

Examples of styrene compounds include, but are not specifically limited to, styrene, α-methylstyrene, 2,4-dimethylstyrene, monochlorostyrene, p-methyl styrene, p-tert-butylstyrene, and ethyl styrene. Of these styrene compounds, styrene is preferable from a viewpoint of raw material practicality.

Examples of compounds that are copolymerizable with a styrene compound include methacrylic acid esters such as methyl methacrylate and ethyl methacrylate; unsaturated nitrile compounds such as acrylonitrile and methacrylonitrile; and acid anhydrides such as maleic anhydride.

In the present embodiment, polystyrene is preferable as a styrene resin from a viewpoint of miscibility with polyphenylene ether. Among polystyrenes, general purpose polystyrene is preferable from a viewpoint of enhancing external appearance of the molded product.

Although the content of the styrene resin (C) is not specifically limited, the content in 100 mass % of the resin composition is preferably 0 mass % to 30 mass %, and more preferably 0 mass % to 25 mass %. Molding fluidity can be enhanced through inclusion of the styrene resin (C) in the resin composition, but the content of the styrene resin (C) is preferably 30 mass % or less from a viewpoint of improving close adhesion and surface reflectance, and from a viewpoint of maintaining high surface reflectance and excellent close adhesion after exposure to high temperature and high humidity conditions.

<Elastomer Component (D)>

An elastomer component (D) may be compounded in the resin composition of the metal thin-film layer-containing laminated molded article of the present embodiment from a viewpoint of improving impact resistance.

The elastomer component (D) may be a commonly known elastomer and, from a viewpoint of heat resistance and miscibility with the polyphenylene ether resin (A) component, preferably includes a block copolymer having a styrene block and a hydrogenated conjugated diene compound block (hereinafter, also referred to as a “styrene block-hydrogenated conjugated diene compound block copolymer”).

From a viewpoint of thermal stability, the conjugated diene compound block is preferably hydrogenated with a hydrogenation rate of 50% or more, more preferably with a hydrogenation rate of 80% or more, and even more preferably with a hydrogenation rate of 95% or more.

Examples of the conjugated diene compound block include, but are not specifically limited to, polybutadiene, polyisoprene, poly(ethylene-butylene), poly(ethylene-propylene), and vinyl-polyisoprene. One type of conjugated diene compound block may be used individually, or two or more types of conjugated diene compound blocks may be used in combination.

The arrangement of repeating units composing the block copolymer may be a linear type or a radial type. Moreover, polystyrene blocks and rubber intermediate blocks may form a two, three, or four block structure. Among such block copolymers, a triblock linear-type block copolymer formed by a polystyrene-poly(ethylene-butylene)-polystyrene structure is preferable from a viewpoint of sufficiently exhibiting the effects that are desired in the present embodiment. Note that the conjugated diene compound blocks may include butadiene units within a range not exceeding 30 mass %.

The styrene block-hydrogenated conjugated diene compound block copolymer that may be used in the present embodiment preferably has a weight average molecular weight Mw within a range of 50,000 to 300,000, more preferably within a range of 70,000 to 280,000, and even more preferably within a range of 100,000 to 250,000 from a viewpoint of enhancing impact resistance. The weight average molecular weight Mw of the styrene block-hydrogenated conjugated diene compound block copolymer is preferably 50,000 or more from a viewpoint of imparting sufficient impact resistance and is preferably 300,000 or less from a viewpoint of molded article fluidity, retention of external appearance, and miscibility.

The styrene block-hydrogenated conjugated diene compound block copolymer that may be used in the present embodiment preferably has a bound styrene content within a range of 20 mass % to 80 mass %, more preferably within a range of 30 mass % to 60 mass %, and even more preferably within a range of 30 mass % to 45 mass %. The bound styrene content of the styrene block-hydrogenated conjugated diene compound block copolymer is preferably 20 mass % or more from a viewpoint of miscibility and is preferably 80 mass % or less from a viewpoint of imparting impact resistance.

Although the content of the elastomer component (D) is not specifically limited, the content in 100 mass % of the resin composition is preferably within a range of 1 mass % to 35 mass %, more preferably within a range of 1 mass % to 32 mass %, and even more preferably within a range of 4 mass % to 30 mass %. An elastomer component (D) content of 1 mass % or more is preferable from a viewpoint of imparting impact resistance required for the applications described herein, whereas an elastomer component (D) content of 35 mass % or less is preferable from a viewpoint of rigidity retention and surface reflectance improvement, and from a viewpoint of maintaining high surface reflectance and excellent close adhesion after exposure to high temperature and high humidity conditions.

<Antioxidant (E)>

The resin composition used in the present embodiment may further contain an antioxidant (E).

Primary antioxidants that act as radical chain inhibitors and secondary antioxidants that have an effect of breaking down peroxides can both be used as the antioxidant (E). In other words, through the use of antioxidants, radicals that may arise at terminal methyl groups and side chain methyl groups when the polyphenylene ether is exposed to a high temperature over a long period can be captured (primary antioxidant) and peroxides that may arise at terminal methyl groups and side chain methyl groups due to the aforementioned radicals can be broken down (secondary antioxidant). Accordingly, oxidative crosslinking of the polyphenylene ether can be prevented.

Hindered phenol antioxidants can mainly be used as primary antioxidants. Specific examples of hindered phenol antioxidants that can be used include 2,6-di-t-butyl-4-methylphenol, pentaerythritol tetrakis[3-(3,5-di-t-butyl-4-hydroxyphenyl)propionate], n-octadecyl-3-(3,5-di-t-butyl-4-hydroxyphenyl)propionate, 2,2′-methylenebis(4-methyl-6-t-butylphenol), 2-t-butyl-6-(3-t-butyl-2-hydroxy-5-methylbenzyl)-4-methylphenyl acrylate, 2-[1-(2-hydroxy-3, 5-di-t-pentylphenyl)ethyl]-4,6-di-t-pentylphenyl acrylate, 4,4′-butylidenebis(3-methyl-6-t-butylphenol), alkylated bisphenol, tetrakis[methylene-3-(3,5-di-t-butyl-4-hydroxyphenyl)propionate]methane, and 3,9-bis[2-{3-(3-t-butyl-4-hydroxy-5-methylphenyl)-propionyloxy}-1,1-dimethylethyl]-2,4,8,10-tetraoxyspiro[5,5]undecane.

Phosphorus-containing antioxidants can mainly be used as secondary antioxidants. Specific examples of phosphorus-containing antioxidants that can be used include trisnonylphenyl phosphite, triphenyl phosphite, tris(2,4-di-t-butylphenyl) phosphite, bis(2,4-di-t-butylphenyl)pentaerythritol-diphosphite, bis(2,6-di-t-butyl-4-methylphenyl)pentaerythritol-diphosphite, and 3,9-bis(2,6-di-tert-butyl-4-methylphenoxy)-2,4,8,10-tetraoxa-3,9-diphosphaspiro[5,5]undecane.

Furthermore, examples of other antioxidants that can be used together with the antioxidants described above include metal oxides such as zinc oxide and magnesium oxide.

Among these antioxidants, a phosphorus-containing antioxidant that acts as a secondary antioxidant is preferable, a phosphite antioxidant is more preferable, and a phosphite antioxidant having the structure in the following chemical formula (12) in molecules thereof is particularly preferable for further enhancing surface appearance of the metal thin-film layer at high temperature or in a high temperature and high humidity environment.

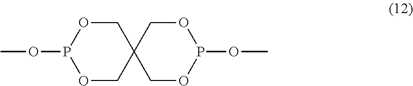

The content of the antioxidant (E) relative to 100 mass % of the resin composition is preferably 0.05 mass % to 5 mass %, more preferably 0.1 mass % to 3.0 mass %, and even more preferably 0.1 mass % to 1.5 mass %. The antioxidant (E) is preferably added in an amount of at least 0.05 mass % and not more than 5 mass % from a viewpoint of obtaining a laminated molded article that has good surface reflectance even after aging in a high temperature and high humidity environment.

Since the laminated molded article of the present embodiment includes the metal thin-film layer, it is preferable that a sulfur-containing antioxidant is not included from a viewpoint of further suppressing corrosion of the metal thin-film layer, and enabling even better surface appearance of the metal thin-film layer of the laminated molded article after the laminated molded article is exposed to high temperature and high humidity over a long period.

Examples of sulfur-containing antioxidants include dilauryl 3,3′-thiodipropionate, dimyristyl 3,3′-thiodipropionate, distearyl 3,3′-thiodipropionate, pentaerythritol tetrakis(β-laurylthiopropionate), ditridecyl 3,3′-thiodipropionate, 2-mercaptobenzimidazole, 2,2-thio-diethylene bis [3-(3,5-di-t-butyl-4-hydroxyphenyl)propionate], 2,2-thiobis(4-methyl-6-t-butylphenol), and 2,4-bis(n-octylthio)-6-(4-hydroxy-3, 5-di-t-butylanilino)-1,3,5-triazine.

<Other Materials (F)>

A colorant such as carbon black, titanium oxide, or another known organic or inorganic dye or pigment may be compounded in the resin composition of the metal thin-film layer-containing laminated molded article of the present embodiment from a viewpoint of coloring.

Carbon black is particularly preferable as a colorant that can be used in the present embodiment from a viewpoint of retaining the properties that are demanded for the applications described herein. In compounding of the carbon black into the resin composition, it is particularly preferable to use what is referred to as a “masterbatch” in which the carbon black is melt-kneaded and mixed into polystyrene in advance from a viewpoint of ease of handling and enhancing dispersibility in the resin composition.

The content of the colorant that may be used in the present embodiment relative to 100 parts by mass, in total, of the resin composition is within a range of 0.01 parts by mass to 8 parts by mass, preferably within a range of 0.1 parts by mass to 5 parts by mass, more preferably within a range of 0.3 parts by mass to 3 parts by mass, and particularly preferably within a range of 0.4 parts by mass to 2 parts by mass. A content of 0.01 parts by mass or more is preferable from a viewpoint of enabling sufficient coloring, whereas a content of 8 parts by mass or less is preferable from a viewpoint of retaining molding external appearance.

So long as heat resistance and mechanical properties of the resin composition and surface appearance, heat aging characteristics after exposure to high temperature and high humidity conditions over a long period, and so forth of the molded product are not significantly reduced, the resin composition of the metal thin-film layer-containing laminated molded article of the present embodiment may contain other antioxidants, ultraviolet absorbers, antistatic agents, lubricants, mold release agents, and the like within a range of 0.001 parts by mass to 3 parts by mass relative to 100 parts by mass of the resin composition, more preferably within a range of 0.01 parts by mass to 0.5 parts by mass, and even more preferably within a range of 0.2 parts by mass to 0.5 parts by mass. The content of these other additives is preferably at least 0.001 parts by mass and not more than 3 parts by mass from a viewpoint of obtaining a laminated molded article that has high surface reflectance.

Moreover, the resin composition of the present embodiment may contain a polycarbonate resin, a polymer alloy including a polycarbonate resin and ABS, a polybutylene terephthalate resin, a polyethylene terephthalate resin, a polyphenylene sulfide resin, or the like as another material (F).

[Method of Producing Resin Composition]

The resin composition of the present embodiment can be produced by melt-kneading raw materials such as the polyphenylene ether resin (A), the amorphous α-olefin copolymer (B), and optional components such as the styrene resin (C), the elastomer component (D), the antioxidant (E), and other materials (F) in the same way as in melt-kneading in the method of synthesizing the polyphenylene ether (i). Although no specific limitations are placed on the conditions of melt-kneading of the components (A), (B), (C), (D), (E), (F), and so forth to produce the resin composition, it is appropriate to use a twin screw extruder having a screw diameter of 25 mm to 90 mm from a viewpoint of stably obtaining a large quantity of a resin composition that can sufficiently exhibit the effects desired in the present embodiment. As one example, in a case in which a TEM58SS twin screw extruder (produced by Toshiba Machine Co., Ltd.; number of barrels: 13; screw diameter: 58 mm; L/D=53; screw pattern including 2 kneading discs L, 14 kneading discs R, and 2 kneading discs N) is used, melt-kneading may be carried out under conditions of a cylinder temperature of 270° C. to 330° C., a screw rotation speed of 150 rpm to 700 rpm, an extrusion rate of 150 kg/h to 600 kg/h, and a vent degree of vacuum of 11.0 kPa to 1.0 kPa.

The temperature of extruded resin is preferably within a range of 250° C. to 380° C. The extruded resin temperature is more preferably within a range of 270° C. to 360° C., and even more preferably within a range of 300° C. to 350° C. An extruded resin temperature of 250° C. or higher is preferable from a viewpoint of extrudability and sufficient expression of the effects required for the applications described herein, whereas an extruded resin temperature of 380° C. or lower is preferable from a viewpoint of extrudability and preventing decomposition of the resin composition.

In a situation in which the resin composition used in the present embodiment is produced using a large-scale (screw diameter: 40 mm to 90 mm) twin screw extruder, it is important to be aware that gel and carbides generated from component (i) in extrusion may become mixed into extruded resin pellets, which may have a negative impact on surface appearance of the molded product and surface reflectance of the laminated molded article. Accordingly, it is preferable that component (A) is fed from a furthest upstream raw material feeding inlet (top feed) and that the oxygen concentration inside a chute of the furthest upstream feeding inlet is set as 15 vol. % or less, more preferably 8 vol. % or less, and even more preferably 1 vol. % or less.

Note that adjustment of the oxygen concentration can be performed by, after sufficiently purging the inside of a raw material storage hopper with nitrogen and tightly sealing a feed line from the raw material storage hopper to the raw material feeding inlet of the extruder such that air does not enter or exit the feed line, adjusting the nitrogen feed rate and the aperture of a gas vent.

[[Metal Thin-Film Layer]]

Examples of the metal of the metal thin-film layer include aluminum, silver, and chromium, with aluminum being particularly preferable in terms of benefiting from light-weight, flexibility, and excellent glossiness.

The thickness of the metal thin-film layer can be appropriately designed in accordance with the use of the laminated molded article without any specific limitations. In the laminated molded article of the present embodiment, the thickness of the metal thin-film layer is preferably 12 nm or less, and more preferably 10 nm or less. A metal thin-film layer thickness of 12 nm or less can prevent peeling of the metal thin-film layer and enables maintenance of high surface reflectance and excellent close adhesion even after exposure to high temperature and high humidity conditions. Moreover, the weight of the metal thin-film layer can be reduced such as to provide a lighter laminated molded article.

Although the surface reflectance of the metal thin-film layer of the laminated molded article in the present embodiment is not specifically limited, the surface reflectance is preferably 70% or more, more preferably 75% or more, even more preferably 80% or more, and particularly preferably 85% or more. When the surface reflectance is within any of the ranges set forth above, the laminated molded article can suitably be used in applications such as automobile optical components, projectors, and various lighting equipment.

The surface reflectance can be measured in accordance with JIS-Z8741. More specifically, the surface reflectance can be measured by a method described in the EXAMPLES section.

The metal thin-film layer-containing laminated molded article of the present embodiment has high surface reflectance, excellent close adhesion between the molded product formed from the resin composition and the metal thin-film layer, and can maintain excellent surface reflectance and close adhesion even after exposure to high temperature and high humidity conditions. Therefore, the laminated molded article of the present embodiment can suitably be used, in particular, as a component for an automobile such as a mirror member or a light-reflecting member of a head-up display.

Moreover, since the laminated molded article of the present embodiment has excellent close adhesion between the molded product formed from the resin composition and the metal thin-film layer, and has high surface reflectance, the thickness of the metal thin-film layer can be reduced such as to reduce the thickness and weight of the laminated molded article. Therefore, the laminated molded article can suitably be used in applications such as automobile optical components, projectors, and various lighting equipment in which demand for weight-reduction has been rising in recent years.

[Method of Producing Laminated Molded Article]

The metal thin-film layer-containing laminated molded article of the present embodiment can be obtained through preparation of a molded product by molding the previously described resin composition and then formation of a metal thin-film layer by a metal vapor deposition process or the like.

[[Molding of Molded Product]]

Examples of suitable methods by which the resin composition may be molded include, but are not limited to, injection molding, extrusion molding, vacuum molding, and pressure forming, with injection molding, in particular, being more preferable from a viewpoint of molding external appearance and brightness.

In terms of the molding temperature in molding of the resin composition, molding is preferably performed with a maximum barrel set temperature within a range of 250° C. to 340° C., more preferably within a range of 270° C. to 330° C., and even more preferably within a range of 280° C. to 320° C. A molding temperature of 250° C. or higher is preferable from a viewpoint of sufficient molding processability, whereas a molding temperature of 340° C. or lower is preferable from a viewpoint of inhibiting resin thermal degradation.

The mold temperature in molding of the resin composition is preferably within a range of 40° C. to 170° C., more preferably within a range of 80° C. to 150° C., and even more preferably within a range of 80° C. to 130° C. A mold temperature of 40° C. or higher is preferable from a viewpoint of retaining adequate molded product external appearance, whereas a mold temperature of 170° C. or lower is preferable from a viewpoint of molding stability.

[[Formation of Metal Thin-Film Layer]]

The method by which the metal thin-film layer is formed is normally a method in which a metal-containing paste is applied or a dry metal plating method. From a viewpoint of forming a uniform metal thin-film layer, vacuum vapor deposition, ion plating, sputtering that is a cross between these techniques, or the like is preferable, and vacuum vapor deposition or sputtering is more preferable.

The following describes, as one example, a specific method of forming the metal thin-film layer by vacuum vapor deposition. The molded product formed from the resin composition is degreased by a method such as dipping in isopropyl alcohol or another solvent. Drying may be performed as necessary at 60° C. to 120° C. A primer (undercoat) may then, as necessary, be applied onto the surface of the degreased molded product and cured. The molded product is set in a supporting jig and is placed in a vacuum vessel. The vacuum vessel is evacuated and then vapor deposition of a vaporized metal such as vaporized metal aluminum is started under a specific pressure. In this vapor deposition, the supporting jig in which the molded product is set may be rotated or revolved above the vapor source as necessary. The thickness of the metal thin-film layer can be designed as appropriate in accordance with the use of the laminated molded article, and vapor deposition of the metal may be performed until a metal thin-film layer of the desired thickness is obtained. After the metal thin-film layer has been formed by vapor deposition, the surface of the metal thin-film layer may be protected through formation of a top coating (also referred to as a transparent protective layer) formed from silicon oxide or the like as necessary.

### EXAMPLES

The following provides a more specific description of the present embodiment through examples and comparative examples. However, the present embodiment is not limited to only these examples. Physical property measurement methods and raw materials used in the examples and comparative examples were as follows.

[Preparation of Laminated Resin Molded Article and Measurement Methods of Physical Properties]

### 1. Preparation of Aluminum Molded Article

Pellets of a resin composition obtained in each of Examples 1 to 13 and 16 to 18, and Comparative Examples 1-4 described below were dried for 3 hours in a 100° C. hot-air dryer. The dried pellets were then molded to form a molded plate using an injection molding machine (IS-80EPN produced by Toshiba Machine Co., Ltd.) equipped with a film gate mirror surface mold measuring 150 mm×150 mm×2 mm in thickness and having a #5000 polished mold surface. The molding was carried out with a cylinder temperature of 320° C., a mold temperature of 120° C., an injection pressure (gauge pressure) of 70 MPa, and an injection rate (panel setting value) of 85%.

The resultant molded plate was placed in a vapor deposition device in a vacuum state. An inert gas and oxygen were introduced into the vapor deposition device and the inside of a chamber of the vapor deposition device was set in a plasma state to perform plasma treatment for activating the surface of the molded plate. Aluminum vapor deposition was then carried out inside the vapor deposition device under vacuum to obtain a laminated molded article including an aluminum vapor deposited layer (metal thin-film layer). The thickness of the metal thin-film layer was 10 nm.

Note that in Example 14, a molded product was obtained in the same way as in Example 1 and then a metal thin-film layer was formed in the same way but with a thickness of 14 nm, and in Example 15, a molded product was obtained in the same way as in Example 8 and then a metal thin-film layer was formed in the same way but with a thickness of 14 nm.

### 2. Surface Reflectance

With respect to laminated molded articles prepared in the following examples and comparative examples, the surface reflectance of the surface of the metal thin-film layer was measured in accordance with JIS-Z8741 using a reflectance meter TR-1100AD/S produced by Tokyo Denshoku Co., Ltd. Three locations in sections of the metal thin-film layer surface that were flat and did not have protrusions were selected as measurement locations and measurement was performed thereat. The measurements were performed at normal temperature and the average value of the measurement results for the three locations was taken to be the surface reflectance.

3. Close Adhesion Between Metal Thin-Film Layer and Molded Product Formed from Resin Composition

With respect to laminated molded articles prepared in the following examples and comparative examples, close adhesion between the metal thin-film layer and the molded product formed from the resin composition was evaluated by a cross-cut method in accordance with JIS-K5600.

The laminated molded article was left for 24 hours at 23° C. and then a blade was used to cut scars in the metal thin-film layer to a depth reaching the molded product at intervals of 1 mm such as to form 100 squares in the surface of the metal thin-film layer. Nichiban adhesive tape (CT-18) was adhered to the metal thin-film layer surface in which the scars had been formed, and was then instantaneously peeled off in a direction at an oblique angle of 30° to peel off the metal thin-film layer. The number of squares of the metal thin-film layer that were peeled off was evaluated as shown below. Note that in a situation in which the number of peeled off squares among the 100 squares is 50 or fewer (i.e., when close adhesion is evaluated as good or excellent), close adhesion between the metal thin-film layer and the molded product is good.

Excellent: Number of peeled off squares among 100 squares is 0 (complete close adhesion) or more, but fewer than 20

Good: Number of peeled off squares among 100 squares is at least 20 and fewer than 50

Unsatisfactory: Number of peeled off squares among 100 squares is at least 50 and fewer than 80

Poor: Number of peeled off squares among 100 squares is at least 80 and not more than 100

### 4. Implementation Method of Aging Test

Laminated molded articles prepared in the following examples and comparative examples were each secured such that the surface of the metal thin-film layer was not in contact with other laminated molded articles in an environment of 60° C. (±5° C.) and 90% RH (±5% RH). After 100 hours had passed, the laminated molded articles were removed and were left for 24 hours at 23° C. before being evaluated for surface reflectance and close adhesion by the previously described methods.

[Raw Materials]

<Polyphenylene Ether (i)>

(i-1)

Poly(2,6-dimethyl-1,4-phenylene) ether was used that had a reduced viscosity (ηsp/c value) of 0.42 dL/g, 0.50 terminal OH groups per 100 monomer units composing the polyphenylene ether, and 0.86 N,N-dibutylaminomethyl groups per 100 monomer units composing the polyphenylene ether.

(i-2)

Poly(2,6-dimethyl-1,4-phenylene) ether was used that had a reduced viscosity (ηsp/c value) of 0.31 dL/g, 0.73 terminal OH groups per 100 monomer units composing the polyphenylene ether, and 0.40 N,N-dibutylaminomethyl groups per 100 monomer units composing the polyphenylene ether.

In the present examples, the reduced viscosity (ηsp/c value) of each polyphenylene ether (i) was measured at 30° C. with respect to a 0.5 g/dL chloroform solution of the polyphenylene ether (i) using an Ubbelohde-type viscometer. The units of reduced viscosity are dL/g.

<Compound (ii)>

(ii)

An organophosphorus compound (chemical name: 9,10-dihydro-9-oxa-10-phosphaphenanthrene-10-oxide; product name: HCA® (HCA is a registered trademark in Japan, other countries, or both); produced by Sanko Co. Ltd.) was used.

<Amorphous α-Olefin Copolymer (B)>

### (B-1)

TAFMER® (TAFMER is a registered trademark in Japan, other countries, or both) P-0680J (specific gravity: 0.870 g/cm³; melt flow rate (190° C., load: 2.16 kg): 0.4 g/10 minutes) produced by Mitsui Chemicals, Inc. was used.

### (B-2)

TAFMER® P-0480 (specific gravity: 0.870 g/cm³; melt flow rate (190° C., load: 2.16 kg): 1.1 g/10 minutes) produced by Mitsui Chemicals, Inc. was used.

### (B-3)

TAFMER® P-0280J (specific gravity: 0.870 g/cm³; melt flow rate (190° C., load: 2.16 kg): 2.9 g/10 minutes) produced by Mitsui Chemicals, Inc. was used.

<Antioxidant (E)>

### (PEP-36)

A phosphorus-containing antioxidant (chemical name: 3,9-bis(2,6-di-tert-butyl-4-methylphenoxy)-2,4,8,10-tetraoxa-3,9-diphosphaspiro[5,5]undecane; produced by ADEKA Corporation; product name: ADK STAB PEP-36® (ADK STAB PEP-36 is a registered trademark in Japan, other countries, or both)) was used (hereinafter, referred to as “PEP-36”).

<Styrene Resin (C)>

### (GPPS)

General purpose polystyrene (product name: Polystyrene 680® (Polystyrene 680 is a registered trademark in Japan, other countries, or both); produced by PS Japan Corporation) was used (hereinafter, referred to as “GPPS”).

<Elastomer Component (D)>

### (SEBS)

A triblock-type hydrogenated block copolymer having a weight average molecular weight of 71,200 and a bound styrene content of 32 mass %, and including polystyrene blocks and hydrogenated butadiene blocks with a hydrogenation rate of 98% was used (hereinafter, referred to as “SEBS”).

### Examples 1, 8, 14, and 15

A tumbler mixer was used to mix 70 parts by mass of (i-1) and 0.7 parts by mass of (ii). The resultant powder mixture was fed from a furthest upstream section (top feed) of a TEM58SS twin screw extruder (produced by Toshiba Machine Co., Ltd.; number of barrels: 13; screw diameter: 58 mm; L/D=53; screw pattern including 2 kneading discs L, 14 kneading discs R, and 2 kneading discs N) and was melt-kneaded under conditions of a cylinder temperature of 300° C., a screw rotation speed of 400 rpm, an extrusion rate of 400 kg/h, and a vent degree of vacuum of 7.998 kPa (60 Torr) to obtain pellets. These pellets were dissolved in chloroform, and were then reprecipitated with methanol to extract a polyphenylene ether component. Thereafter, vacuum drying was performed for 4 hours at 60° C. to obtain a polyphenylene ether powder.

It was possible to identify the obtained polyphenylene ether powder by ³¹P-NMR (single-pulse method) and ¹H-NMR. The added amount of reactive compound was determined by dividing an integral value of a peak appearing at 2.8 ppm to 3.6 ppm in ¹H-NMR by an integral value of a peak appearing at 6.0 ppm to 7.0 ppm in ¹H-NMR that originates from aromatic rings of the polyphenylene ether. It was confirmed that the total number of structural units represented by the following chemical formulae (9) and (10) per 100 monomer units in the polyphenylene ether chain was 0.30 units.

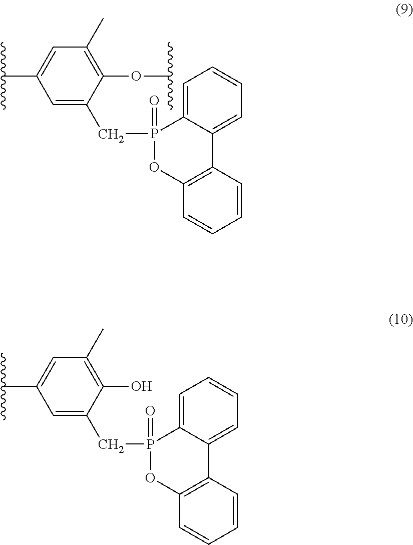

³¹P-NMR measurement conditions

Device: JEOL RESONANCE ECS400

Observed nucleus: ³¹P

Observation frequency: 161.8 MHz

Pulse width: 45°

Wait time: 5 sec

Number of scans: 10,000

Solvent: CDCl₃

Sample concentration: 20 w/v %

Chemical shift standard: 85% phosphoric acid aqueous solution (external standard) 0 ppm

¹H-NMR measurement conditions

Device: JEOL-ECA 500

Observed nucleus: ¹H

Observation frequency: 500.16 MHz

Measurement method: Single-Pulse

Pulse width: 7 μsec

Wait time: 5 sec

Number of scans: 512

Solvent: CDCl₃

Sample concentration: 5 w %

Chemical shift standard: TMS 0.00 ppm

Measurement of polyphenylene ethers by ³¹P-NMR and ¹H-NMR described below was carried out using the above conditions.

It was possible to determine the added amount of the reactive compound to terminal hydroxy groups by the following equation (1) using an integral value [A] of a peak at 146.4 ppm in ¹³C-NMR (carbon adjacent to oxygen atom of ether bond formed through addition of reactive compound to OH group) and an integral value [B] at 145.4 ppm in ¹³C-NMR (carbon adjacent to OH group). It was confirmed that 0.02 structural units represented by the following chemical formula (11) were included per 100 monomer units composing the polyphenylene ether.

Added amount of reactive compound (molecules) per 100 monomer units composing polyphenylene ether=(Number of terminal OH groups per 100 monomer units composing precursor polyphenylene ether)×{[A]/([A]+[B])} (1)

Moreover, it was confirmed that a new doublet peak did not arise at 3.5 ppm to 5.5 ppm in ¹H-NMR.

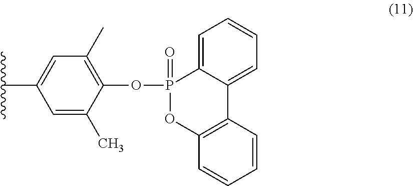 [SMILES: *c1cc(C)c(OP2(=O)Oc3ccccc3-c3ccccc32)c(C)c1]

¹³C-NMR measurement conditions

Device: Bruker Biospin Avance 600

Observed nucleus: ¹³C

Observation frequency: 150.9 MHz

Measurement method: Inverse gated decoupling

Pulse width: 30°

Wait time: 10 sec

Number of scans: 2,000

Solvent: CDCl₃

Sample concentration: 20 w/v %

Chemical shift standard: TMS 0 ppm

Measurement of polyphenylene ethers by ¹³C-NMR described below was carried out using the above conditions.

The ratio of structural units represented by chemical formula (9) relative to structural units represented by chemical formula (10) was determined to be 25 mol % by calculating a ratio of an integral value of a peak at 34 ppm to 36 ppm in ³¹P-NMR originating from structural units represented by chemical formula (9) relative to an integral value of a peak at 38 ppm to 42 ppm in ³¹P-NMR originating from structural units represented by chemical formula (10).

Resin compositions were obtained using the resultant pellets, a styrene resin (GPPS), an elastomer component (SEBS), an antioxidant (PEP-36), and an amorphous α-olefin copolymer (B-1) by feeding these materials from a furthest upstream section (top feed) of a TEM58SS twin screw extruder (produced by Toshiba Machine Co., Ltd.; number of barrels: 13; screw diameter: 58 mm; L/D=53; screw pattern including 2 kneading discs L, 14 kneading discs R, and 2 kneading discs N) in compounding ratios shown in Tables 1 and 2 and performing melt-kneading thereof under conditions of a cylinder temperature of 300° C., a screw rotation speed of 400 rpm, an extrusion rate of 400 kg/h, and a vent degree of vacuum of 7.998 kPa (60 Torr).

### Examples 2 and 10

A mixture of 70 parts by mass of (i-2) and 0.7 parts by mass of (ii) was melt-kneaded to obtain pellets in the same way as in Example 1. The obtained pellets were converted to a polyphenylene ether powder and the added amount of reactive compound was quantified in the same way as in Example 1. As a result, it was confirmed that the total number of structural units represented by chemical formulae (9) and (10) per 100 monomer units in the polyphenylene ether chain was 0.26 units.

Moreover, it was possible to determine the added amount of the reactive compound to terminal hydroxy groups by the preceding equation (1) using an integral value [A] of a peak at 146.4 ppm in ¹³C-NMR (carbon adjacent to oxygen atom of ether bond formed through addition of reactive compound to OH group) and an integral value [B] at 145.4 ppm in ¹³C-NMR (carbon adjacent to OH group). It was confirmed that 0.04 structural units represented by chemical formula (11) were included per 100 monomer units composing the polyphenylene ether. Furthermore, it was confirmed that a new doublet peak did not arise at 3.5 ppm to 5.5 ppm in ¹H-NMR.

The ratio of structural units represented by chemical formula (9) relative to structural units represented by chemical formula (10) was determined to be 27 mol % by calculating a ratio of an integral value of a peak at 34 ppm to 36 ppm in ³¹P-NMR originating from structural units represented by chemical formula (9) relative to an integral value of a peak at 38 ppm to 42 ppm in ³¹P-NMR originating from structural units represented by chemical formula (10).

Resin compositions were obtained using the resultant pellets, a styrene resin (GPPS), an elastomer component (SEBS), an antioxidant (PEP-36), and an amorphous α-olefin copolymer (B-1) by melt kneading these materials in compounding ratios shown in Table 1.

### Examples 3, 4, 5, 6, 7, 12, and 18

A mixture of 40 parts by mass of (i-1), 30 parts by mass of (i-2), and 0.7 parts by mass of (ii) was melt-kneaded to obtain pellets in the same way as in Example 1. The obtained pellets were converted to a polyphenylene ether powder and the added amount of reactive compound was quantified in the same way as in Example 1. As a result, it was confirmed that the total number of structural units represented by chemical formulae (9) and (10) per 100 monomer units in the polyphenylene ether chain was 0.28 units.

Moreover, it was possible to determine the added amount of the reactive compound to terminal hydroxy groups by the preceding equation (1) using an integral value [A] of a peak at 146.4 ppm in ¹³C-NMR (carbon adjacent to oxygen atom of ether bond formed through addition of reactive compound to OH group) and an integral value [B] at 145.4 ppm in ¹³C-NMR (carbon adjacent to OH group). It was confirmed that 0.03 structural units represented by chemical formula (11) were included per 100 monomer units composing the polyphenylene ether. Furthermore, it was confirmed that a new doublet peak did not arise at 3.5 ppm to 5.5 ppm in ¹H-NMR.

The ratio of structural units represented by chemical formula (9) relative to structural units represented by chemical formula (10) was determined to be 26 mol % by calculating a ratio of an integral value of a peak at 34 ppm to 36 ppm in ³¹P-NMR originating from structural units represented by chemical formula (9) relative to an integral value of a peak at 38 ppm to 42 ppm in ³¹P-NMR originating from structural units represented by chemical formula (10).

Resin compositions were obtained using the resultant pellets, a styrene resin (GPPS), an elastomer component (SEBS), and amorphous α-olefin copolymers (B-1) to (B-3) by melt-kneading these materials in compounding ratios shown in Tables 1 and 2.

### Example 9

A mixture of 70 parts by mass of (i-1) and 0.35 parts by mass of (ii) was melt-kneaded to obtain pellets in the same way as in Example 1. The obtained pellets were converted to a polyphenylene ether powder and the added amount of reactive compound was quantified in the same way as in Example 1. As a result, it was confirmed that the total number of structural units represented by chemical formulae (9) and (10) per 100 monomer units in the polyphenylene ether chain was 0.14 units.

Moreover, it was possible to determine the added amount of the reactive compound to terminal hydroxy groups by the preceding equation (1) using an integral value [A] of a peak at 146.4 ppm in ¹³C-NMR (carbon adjacent to oxygen atom of ether bond formed through addition of reactive compound to OH group) and an integral value [B] at 145.4 ppm in ¹³C-NMR (carbon adjacent to OH group). It was confirmed that 0.01 structural units represented by chemical formula (11) were included per 100 monomer units composing the polyphenylene ether. Furthermore, it was confirmed that a new doublet peak did not arise at 3.5 ppm to 5.5 ppm in ¹H-NMR.

The ratio of structural units represented by chemical formula (9) relative to structural units represented by chemical formula (10) was determined to be 23 mol % by calculating a ratio of an integral value of a peak at 34 ppm to 36 ppm in ³¹P-NMR originating from structural units represented by chemical formula (9) relative to an integral value of a peak at 38 ppm to 42 ppm in ³¹P-NMR originating from structural units represented by chemical formula (10).

A resin composition was obtained using the resultant pellets, a styrene resin (GPPS), an elastomer component (SEBS), an antioxidant (PEP-36), and an amorphous α-olefin copolymer (B-1) by melt-kneading these materials in a compounding ratio shown in Table 1.

### Example 11

A mixture of 70 parts by mass of (i-2) and 0.35 parts by mass of (ii) was melt-kneaded to obtain pellets in the same way as in Example 1. The obtained pellets were converted to a polyphenylene ether powder and the added amount of reactive compound was quantified in the same way as in Example 1. As a result, it was confirmed that the total number of structural units represented by chemical formulae (9) and (10) per 100 monomer units in the polyphenylene ether chain was 0.13 units.

Moreover, it was possible to determine the added amount of the reactive compound to terminal hydroxy groups by the preceding equation (1) using an integral value [A] of a peak at 146.4 ppm in ¹³C-NMR (carbon adjacent to oxygen atom of ether bond formed through addition of reactive compound to OH group) and an integral value [B] at 145.4 ppm in ¹³C-NMR (carbon adjacent to OH group). It was confirmed that 0.01 structural units represented by chemical formula (11) were included per 100 monomer units composing the polyphenylene ether. Furthermore, it was confirmed that a new doublet peak did not arise at 3.5 ppm to 5.5 ppm in ¹H-NMR.

The ratio of structural units represented by chemical formula (9) relative to structural units represented by chemical formula (10) was determined to be 24 mol % by calculating a ratio of an integral value of a peak at 34 ppm to 36 ppm in ³¹P-NMR originating from structural units represented by chemical formula (9) relative to an integral value of a peak at 38 ppm to 42 ppm in ³¹P-NMR originating from structural units represented by chemical formula (10).

A resin composition was obtained using the resultant pellets, a styrene resin (GPPS), an elastomer component (SEBS), an antioxidant (PEP-36), and an amorphous α-olefin copolymer (B-1) by melt-kneading these materials in a compounding ratio shown in Table 1.

### Example 13

A mixture of 40 parts by mass of (i-1), 30 parts by mass of (i-2), and 0.35 parts by mass of (ii) was melt-kneaded to obtain pellets in the same way as in Example 1. The obtained pellets were converted to a polyphenylene ether powder and the added amount of reactive compound was quantified in the same way as in Example 1. As a result, it was confirmed that the total number of structural units represented by chemical formulae (9) and (10) per 100 monomer units in the polyphenylene ether chain was 0.14 units.

Moreover, it was possible to determine the added amount of the reactive compound to terminal hydroxy groups by the preceding equation (1) using an integral value [A] of a peak at 146.4 ppm in ¹³C-NMR (carbon adjacent to oxygen atom of ether bond formed through addition of reactive compound to OH group) and an integral value [B] at 145.4 ppm in ¹³C-NMR (carbon adjacent to OH group). It was confirmed that 0.02 structural units represented by chemical formula (11) were included per 100 monomer units composing the polyphenylene ether. Furthermore, it was confirmed that a new doublet peak did not arise at 3.5 ppm to 5.5 ppm in ¹H-NMR.

The ratio of structural units represented by chemical formula (9) relative to structural units represented by chemical formula (10) was determined to be 24 mol % by calculating a ratio of an integral value of a peak at 34 ppm to 36 ppm in ³¹P-NMR originating from structural units represented by chemical formula (9) relative to an integral value of a peak at 38 ppm to 42 ppm in ³¹P-NMR originating from structural units represented by chemical formula (10).

A resin composition was obtained using the resultant pellets, a styrene resin (GPPS), an elastomer component (SEBS), an antioxidant (PEP-36), and an amorphous α-olefin copolymer (B-1) by melt-kneading these materials in a compounding ratio shown in Table 2.

### Comparative Examples 1, 2, and 3

Resin compositions were obtained using a polyphenylene ether (i-1) and/or (i-2), a styrene resin (GPPS), and an elastomer component (SEBS) by feeding these materials from a furthest upstream section (top feed) of a TEM58SS twin screw extruder (produced by Toshiba Machine Co. Ltd.; number of barrels: 13; screw diameter: 58 mm; L/D=53; screw pattern including 2 kneading discs L, 14 kneading discs R, and 2 kneading discs N) in compounding ratios shown in Table 2 and performing melt-kneading thereof under conditions of a cylinder temperature of 300° C., a screw rotation speed of 400 rpm, an extrusion rate of 400 kg/h, and a vent degree of vacuum of 7.998 kPa (60 Torr).

### Comparative Example 4

A mixture of 70 parts by mass of (i-2) and 3 parts by mass of (ii) was melt-kneaded to obtain pellets in the same way as in Example 1. The obtained pellets were converted to a polyphenylene ether powder and the added amount of reactive compound was quantified in the same way as in Example 1. As a result, it was confirmed that the total number of structural units represented by chemical formulae (9) and (10) per 100 monomer units in the polyphenylene ether chain was 2.1 units.

Moreover, it was possible to determine the added amount of the reactive compound to terminal hydroxy groups by the preceding equation (1) using an integral value [A] of a peak at 146.4 ppm in ¹³C-NMR (carbon adjacent to oxygen atom of ether bond formed through addition of reactive compound to OH group) and an integral value [B] at 145.4 ppm in ¹³C-NMR (carbon adjacent to OH group). It was confirmed that 0.82 structural units represented by chemical formula (11) were included per 100 monomer units composing the polyphenylene ether. Furthermore, it was confirmed that a new doublet peak did not arise at 3.5 ppm to 5.5 ppm in ¹H-NMR.

The ratio of structural units represented by chemical formula (9) relative to structural units represented by chemical formula (10) was determined to be 23 mol % by calculating a ratio of an integral value of a peak at 34 ppm to 36 ppm in ³¹P-NMR originating from structural units represented by chemical formula (9) relative to an integral value of a peak at 38 ppm to 42 ppm in ³¹P-NMR originating from structural units represented by chemical formula (10).

A resin composition was obtained using the resultant pellets, a styrene resin (GPPS), and an elastomer component (SEBS) by melt-kneading these materials in a compounding ratio shown in Table 2.

### Examples 16 and 17

A mixture of 58 parts by mass of (i-1) and 0.35 parts by mass of (ii) was melt-kneaded to obtain pellets in the same way as in Example 1. The obtained pellets were converted to a polyphenylene ether powder and the added amount of reactive compound was quantified in the same way as in Example 1. As a result, it was confirmed that the total number of structural units represented by chemical formulae (9) and (10) per 100 monomer units in the polyphenylene ether chain was 0.15 units.

Moreover, it was possible to determine the added amount of the reactive compound to terminal hydroxy groups by the preceding equation (1) using an integral value [A] of a peak at 146.4 ppm in ¹³C-NMR (carbon adjacent to oxygen atom of ether bond formed through addition of reactive compound to OH group) and an integral value [B] at 145.4 ppm in ¹³C-NMR (carbon adjacent to OH group). It was confirmed that 0.03 structural units represented by chemical formula (11) were included per 100 monomer units composing the polyphenylene ether. Furthermore, it was confirmed that a new doublet peak did not arise at 3.5 ppm to 5.5 ppm in ¹H-NMR.

The ratio of structural units represented by chemical formula (9) relative to structural units represented by chemical formula (10) was determined to be 23 mol % by calculating a ratio of an integral value of a peak at 34 ppm to 36 ppm in ³¹P-NMR originating from structural units represented by chemical formula (9) relative to an integral value of a peak at 38 ppm to 42 ppm in ³¹P-NMR originating from structural units represented by chemical formula (10).

A resin composition was obtained using the resultant pellets, a styrene resin (GPPS), an elastomer component (SEBS), an antioxidant (PEP-36), and an amorphous α-olefin copolymer (B-1) by melt-kneading these materials in a compounding ratio shown in Table 2.

The results of evaluation of physical properties of laminated molded articles (aluminum molded articles) prepared as described above using the resin compositions obtained in Examples 1 to 18 and Comparative Examples 1 to 4 are shown in the following Tables 1 and 2.

TABLE 1

| | | | Example | Example | Example | Example | Example | Example |
|---|---|---|---|---|---|---|---|---|
| | | | 1 | 2 | 3 | 4 | 5 | 6 |
| Polyphenylene | PPE (i-1) | Parts by mass | 70 | — | 40 | 40 | 40 | 40 |
| ether resin (A) | PPE (i-2) | Parts by mass | — | 70 | 30 | 30 | 30 | 30 |
| | HCA (ii) | Parts by mass | 0.7 | 0.7 | 0.7 | 0.7 | 0.7 | 0.7 |
| Antioxidant (E) | PEP-36 | Parts by mass | — | — | — | — | — | — |
| Styrene resin (C) | GPPS | Parts by mass | — | — | — | — | — | 15 |
| Elastomer | SEBS | Parts by mass | 29.3 | 29.3 | 29.3 | 29.3 | 29.3 | 14.3 |
| component (D) | | | | | | | | |
| Amorphous | B-1 | Parts by mass | 0.5 | 0.5 | 0.5 | — | — | 0.5 |
| α-olefin | B-2 | Parts by mass | — | — | — | 0.5 | — | — |
| copolymer (B) | B-3 | Parts by mass | — | — | — | — | 0.5 | — |
| Content of (ii) relative to 100 | | Mass % | 0.99 | 0.99 | 0.99 | 0.99 | 0.99 | 0.99 |
| mass %, in total, of (i) and (ii) | | | | | | | | |
| Content of (B) relative to 100 | | Mass % | 0.71 | 0.71 | 0.71 | 0.71 | 0.71 | 0.71 |
| mass % of (A) | | | | | | | | |
| Content of structural units | | Units | 0.30 | 0.26 | 0.28 | 0.28 | 0.28 | 0.28 |
| represented by formula (9) and/or | | | | | | | | |
| (10) per 100 monomer units | | | | | | | | |
| of PPE in (A) | | | | | | | | |
| Ratio of structural units | | Mol % | 25 | 27 | 26 | 26 | 26 | 26 |
| represented by formula (9) | | | | | | | | |
| relative to structural units | | | | | | | | |
| represented by formula (10) in (A) | | | | | | | | |
| Content of structural units | | Units | 0.02 | 0.04 | 0.03 | 0.03 | 0.03 | 0.03 |
| represented by formula (11) per | | | | | | | | |
| 100 monomer units of PPE in (A) | | | | | | | | |
| Metal thin-film layer thickness | | nm | 10 | 10 | 10 | 10 | 10 | 10 |
| Pre-aging | Close adhesion | — | Excellent | Excellent | Excellent | Excellent | Excellent | Excellent |
| | evaluation | | | | | | | |
| | Surface | % | 86 | 88 | 88 | 83 | 80 | 85 |
| | reflectance | | | | | | | |
| Post-aging | Close adhesion | — | Excellent | Excellent | Excellent | Excellent | Excellent | Excellent |
| at 60° C. and | evaluation | | | | | | | |
| 90% RH | Surface | % | 84 | 86 | 86 | 81 | 78 | 83 |
| | reflectance | | | | | | | |

| | | | Example | Example | Example | Example | Example |
|---|---|---|---|---|---|---|---|
| | | | 7 | 8 | 9 | 10 | 11 |
| Polyphenylene | PPE (i-1) | Parts by mass | 40 | 70 | 70 | — | — |
| ether resin (A) | PPE (i-2) | Parts by mass | 30 | — | — | 70 | 70 |
| | HCA (ii) | Parts by mass | 0.7 | 0.7 | 0.35 | 0.7 | 0.35 |
| Antioxidant (E) | PEP-36 | Parts by mass | — | — | 0.35 | — | 0.35 |
| Styrene resin (C) | GPPS | Parts by mass | — | 24.3 | 24.3 | 24.3 | 24.3 |
| Elastomer | SEBS | Parts by mass | 29.3 | 5 | 5 | 5 | 5 |
| component (D) | | | | | | | |
| Amorphous | B-1 | Parts by mass | 1.5 | 0.5 | 0.5 | 0.5 | 0.5 |
| α-olefin | B-2 | Parts by mass | — | — | — | — | — |
| copolymer (B) | B-3 | Parts by mass | — | — | — | — | — |
| Content of (ii) relative to 100 | | Mass % | 0.99 | 0.99 | 0.50 | 0.99 | 0.50 |
| mass %, in total, of (i) and (ii) | | | | | | | |
| Content of (B) relative to 100 | | Mass % | 2.1 | 0.71 | 0.71 | 0.71 | 0.71 |
| mass % of (A) | | | | | | | |
| Content of structural units | | Units | 0.28 | 0.30 | 0.14 | 0.26 | 0.13 |
| represented by formula (9) and/or | | | | | | | |
| (10) per 100 monomer units | | | | | | | |
| of PPE in (A) | | | | | | | |
| Ratio of structural units | | Mol % | 26 | 25 | 23 | 27 | 24 |
| represented by formula (9) | | | | | | | |
| relative to structural units | | | | | | | |
| represented by formula (10) in (A) | | | | | | | |
| Content of structural units | | Units | 0.03 | 0.02 | 0.01 | 0.04 | 0.01 |
| represented by formula (11) per | | | | | | | |
| 100 monomer units of PPE in (A) | | | | | | | |
| Metal thin-film layer thickness | | nm | 10 | 10 | 10 | 10 | 10 |
| Pre-aging | Close adhesion | — | Excellent | Excellent | Excellent | Excellent | Excellent |
| | evaluation | | | | | | |
| | Surface | % | 86 | 93 | 92 | 92 | 92 |
| | reflectance | | | | | | |
| Post-aging | Close adhesion | — | Excellent | Excellent | Excellent | Excellent | Excellent |
| at 60° C. and | evaluation | | | | | | |
| 90% RH | Surface | % | 84 | 91 | 91 | 91 | 91 |
| | reflectance | | | | | | |

TABLE 2

| | | | Comparative | Comprative | Comparative | Comparative | | |
|---|---|---|---|---|---|---|---|---|
| | | | Example | Example | Example | Example | Example | Example |
| | | | 1 | 2 | 3 | 4 | 12 | 13 |
| Polyphenylene | PPE (i-1) | Parts by mass | 70 | — | 40 | — | 40 | 40 |
| ether resin (A) | PPE (i-2) | Parts by mass | — | 70 | 30 | 70 | 30 | 30 |
| | HCA (ii) | Parts by mass | — | — | — | 3 | 0.7 | 0.35 |
| Antioxidant (E) | PEP-36 | Parts by mass | — | — | — | — | — | 0.35 |
| Styrene resin (C) | GPPS | Parts by mass | 25 | 25 | 25 | 27 | 24.3 | 24.3 |
| Elastomer | SEBS | Parts by mass | 5 | 5 | 5 | — | 5 | 5 |
| component (D) | | | | | | | | |
| Amorphous | B-1 | Parts by mass | — | — | — | — | 0.5 | 0.5 |
| α-olefin | B-2 | Parts by mass | — | — | — | — | — | — |
| copolymer (B) | B-3 | Parts by mass | — | — | — | — | — | — |
| Content of (ii) relative to 100 | | Mass % | — | — | — | 4.11 | 0.99 | 0.50 |
| mass %, in total, of (i) and (ii) | | | | | | | | |
| Content of (B) relative to 100 | | Mass % | — | — | — | — | 0.71 | 0.71 |
| mass % of (A) | | | | | | | | |
| Content of structural units | | Units | — | — | — | 2.1 | 0.28 | 0.14 |
| represented by formula (9) and/or | | | | | | | | |
| (10) per 100 monomer units | | | | | | | | |
| of PPE in (A) | | | | | | | | |
| Ratio of structural units | | Mol % | — | — | — | 23 | 26 | 24 |
| represented by formula (9) | | | | | | | | |
| relative to structural units | | | | | | | | |
| represented by formula (10) in (A) | | | | | | | | |
| Content of structural units | | Units | — | — | — | 0.82 | 0.03 | 0.02 |
| represented by formula (11) per | | | | | | | | |
| 100 monomer units of PPE in (A) | | | | | | | | |
| Metal thin-film layer thickness | | nm | 10 | 10 | 10 | 10 | 10 | 10 |
| Pre-aging | Close adhesion | — | Unsatis- | Unsatis- | Unsatis- | Unsatis- | Excellent | Excellent |
| | evaluation | | factory | factory | factory | factory | | |
| | Surface | % | 63 | 63 | 63 | 65 | 93 | 90 |
| | reflectance | | | | | | | |
| Post-aging | Close adhesion | — | Poor | Poor | Poor | Poor | Excellent | Excellent |
| at 60° C. and | evaluation | | | | | | | |
| 90% RH | Surface | % | 60 | 60 | 60 | 62 | 91 | 87 |
| | reflectance | | | | | | | |
| | | | | Example | Example | Example | Example | Example |
| | | | | 14 | 15 | 16 | 17 | 18 |
| | Polyphenylene | PPE (i-1) | Parts by mass | 70 | 70 | 58 | 58 | 40 |
| | ether resin (A) | PPE (i-2) | Parts by mass | — | — | — | — | 30 |
| | | HCA (ii) | Parts by mass | 0.7 | 0.7 | 0.35 | 0.35 | 0.7 |
| | Antioxidant (E) | PEP-36 | Parts by mass | — | — | 0.35 | 0.35 | — |
| | Styrene resin (C) | GPPS | Parts by mass | — | 24.3 | 36.3 | 4.3 | — |
| | Elastomer | SEBS | Parts by mass | 29.3 | 5 | 5 | 37 | 29.3 |
| | component (D) | | | | | | | |
| | Amorphous | B-1 | Parts by mass | 0.5 | 0.5 | 0.5 | 0.5 | 5 |
| | α-olefin | B-2 | Parts by mass | — | — | — | — | — |
| | copolymer (B) | B-3 | Parts by mass | — | — | — | — | — |
| | Content of (ii) relative to 100 | | Mass % | 0.99 | 0.99 | 0.60 | 0.60 | 0.99 |
| | mass %, in total, of (i) and (ii) | | | | | | | |
| | Content of (B) relative to 100 | | Mass % | 0.71 | 0.71 | 0.86 | 0.86 | 7.1 |
| | mass % of (A) | | | | | | | |
| | Content of structural units | | Units | 0.30 | 0.30 | 0.15 | 0.15 | 0.28 |
| | represented by formula (9) and/or | | | | | | | |
| | (10) per 100 monomer units | | | | | | | |
| | of PPE in (A) | | | | | | | |
| | Ratio of structural units | | Mol % | 25 | 25 | 23 | 23 | 26 |
| | represented by formula (9) | | | | | | | |
| | relative to structural units | | | | | | | |
| | represented by formula (10) in (A) | | | | | | | |
| | Content of structural units | | Units | 0.02 | 0.02 | 0.03 | 0.03 | 0.03 |
| | represented by formula (11) per | | | | | | | |
| | 100 monomer units of PPE in (A) | | | | | | | |
| | Metal thin-film layer thickness | | nm | 14 | 14 | 10 | 10 | 10 |
| | Pre-aging | Close adhesion | — | Good | Good | Good | Good | Good |
| | | evaluation | | | | | | |
| | | Surface | % | 83 | 92 | 78 | 79 | 77 |
| | | reflectance | | | | | | |
| | Post-aging | Close adhesion | — | Poor | Poor | Unsatis- | Unsatis- | Unsatis- |
| | at 60° C. and | evaluation | | | | factory | factory | factory |
| | 90% RH | Surface | % | 58 | 65 | 76 | 76 | 75 |
| | | reflectance | | | | | | |

As can be seen from Tables 1 and 2, laminated molded articles that were prepared using molded products formed from the resin compositions of Examples 1 to 18 each had excellent close adhesion between the molded product and a metal thin-film layer and high surface reflectance, and thus can favorably be used as laminated molded articles in the applications described herein.

### INDUSTRIAL APPLICABILITY

The presently disclosed laminated molded article has high surface reflectance, excellent close adhesion between a molded product formed from a resin composition and a metal thin-film layer, and can maintain high surface reflectance and excellent close adhesion even after exposure to high temperature and high humidity conditions. Therefore, the presently disclosed laminated molded article can suitably be used as a molded article for a light-reflecting component such as a mirror member of a head-up display or other automobile component.

1. A laminated molded article comprising:
a molded product formed from a resin composition; and
a metal thin-film layer, wherein
the resin composition contains a polyphenylene ether resin (A) and an amorphous α-olefin copolymer (B), and
the polyphenylene ether resin (A) includes a polyphenylene ether (i) and a compound (ii) being at least one compound selected from the group consisting of: an organophosphorus compound having, in molecules thereof, a chemical structure represented by formula (I) or (II), shown below, 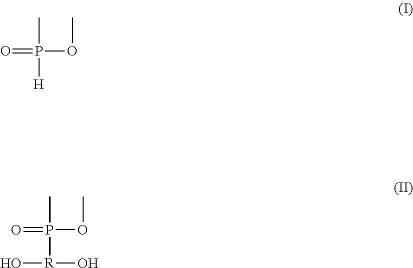
where R in formula (II) is a trivalent saturated hydrocarbon group having a carbon number of 1 to 8 or a trivalent aromatic hydrocarbon group having a carbon number of 6 to 12; and a phosphonic acid, phosphonic acid ester, phosphinic acid, phosphinic acid ester, monocarboxylic acid, sulfonic acid, sulfinic acid, or carbonate other than the organophosphorus compound in amounts of 95 mass % to 99.95 mass % of the component (i) and 0.05 mass % to 5 mass % of the component (ii) relative to 100 mass %, in total, of the components (i) and (ii).

2. The laminated molded article according to claim 1, wherein
the resin composition contains 0.1 mass % to 3 mass % of the amorphous α-olefin copolymer (B) relative to 100 mass % of the polyphenylene ether resin (A).

3. The laminated molded article according to claim 1, wherein
the resin composition contains 59 mass % to 98 mass % of the polyphenylene ether resin (A), 0 mass % to 30 mass % of a styrene resin (C), and 1 mass % to 35 mass % of an elastomer component (D) relative to 100 mass % of the resin composition.

4. The laminated molded article according to claim 1, wherein
the polyphenylene ether (i) includes at least one structural unit selected from the group consisting of chemical formulae (1), (2), and (3), shown below, 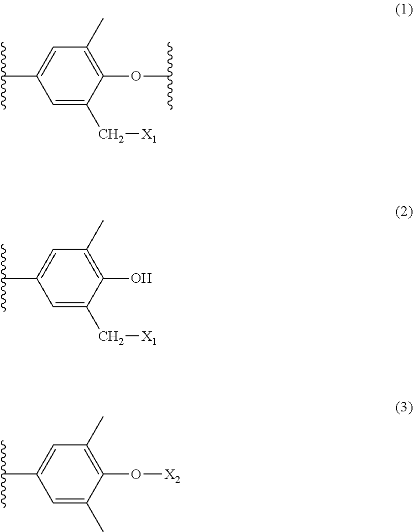
where X₁ in chemical formulae (1) and (2) is one group selected from 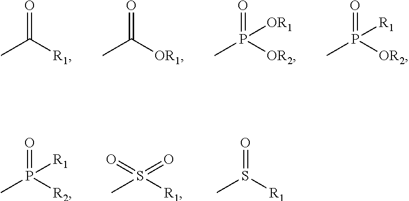
with R₁ and R₂ in X₁ each being, independently of one another, a substituent having a carbon number of 1 or more, and
X₂ in chemical formula (3) is one group selected from the group consisting of 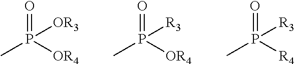
with R₃ and R₄ in X₂ each being, independently of one another, a group selected from the group consisting of a hydrogen atom, an alkyl group, an aryl group, an alkylamino group, and an arylamino group, where R₃ and R₄ may form a cyclic structure through bonding of respective carbon atoms included therein, and chemical formula (3) does not substantially include an unsaturated double bond other than an aromatic ring unsaturated double bond.

5. The laminated molded article according to claim 4, wherein
the at least one structural unit selected from the group consisting of chemical formulae (1), (2), and (3) is contained in a ratio of 0.01 units to 10.0 units per 100 monomer units composing the polyphenylene ether (i).

6. The laminated molded article according to claim 4, wherein
a ratio of a structural unit represented by chemical formula (1) relative to a structural unit represented by chemical formula (2) in the polyphenylene ether (i) is 0 mol % to 30 mol %.

7. The laminated molded article according to claim 4, wherein
the polyphenylene ether (i) includes a structural unit represented by chemical formula (3) and either or both of a structural unit represented by chemical formula (1) and a structural unit represented by chemical formula (2).

8. The laminated molded article according to claim 1, wherein
the polyphenylene ether (i) includes at least one structural unit selected from the group consisting of chemical formulae (4), (5), and (6), shown below, 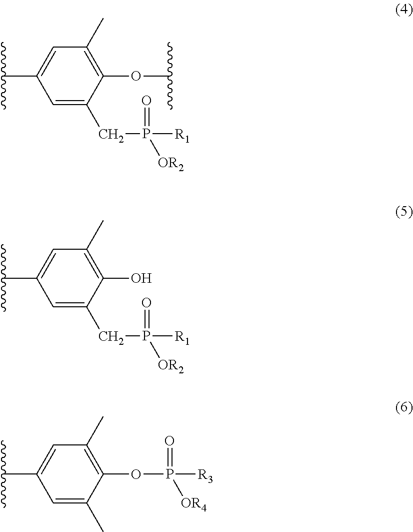
where R₁ and R₂ in chemical formulae (4) and (5) are each, independently of one another, a substituent having a carbon number of 1 or more, R₃ and R₄ in chemical formula (6) are each, independently of one another, a group selected from the group consisting of a hydrogen atom, an alkyl group, an aryl group, an alkylamino group, and an arylamino group, R₃ and R₄ may form a cyclic structure through bonding of respective carbon atoms included therein, and chemical formula (6) does not substantially include an unsaturated double bond other than an aromatic ring unsaturated double bond.

9. The laminated molded article according to claim 1, wherein
the metal thin-film layer has a thickness of 12 nm or less.

10. The laminated molded article according to claim 1, wherein
the metal thin-film layer is a vapor deposited film formed from aluminum.

11. The laminated molded article according to claim 1, wherein
the metal thin-film layer has a thickness of 12 nm or less, and.
the metal thin-film layer is a vapor deposited film formed from aluminum.

12. The laminated molded article according to claim 1, wherein
the resin composition contains 0.1 mass % to 3 mass % of the amorphous α-olefin copolymer (B) relative to 100 mass % of the polyphenylene ether resin (A),
the resin composition contains 59 mass % to 98 mass % of the polyphenylene ether resin (A), 0 mass % to 30 mass % of a styrene resin (C), and 1 mass % to 35 mass % of an elastomer component (D) relative to 100 mass % of the resin composition,
the metal thin-film layer has a thickness of 12 nm or less, and
the metal thin-film layer is a vapor deposited film formed from aluminum.

13. A laminated molded article comprising:
a molded product formed from a resin composition; and
a metal thin-film layer, wherein
the resin composition contains a polyphenylene ether resin (A) and an amorphous α-olefin copolymer (B),
the resin composition contains 0.1 mass % to 3 mass % of the amorphous α-olefin copolymer (B) relative to 100 mass % of the polyphenylene ether resin (A),
the resin composition contains 59 mass % to 98 mass % of the polyphenylene ether resin (A), 0 mass % to 30 mass % of a styrene resin (C), and 1 mass % to 35 mass % of an elastomer component (D) relative to 100 mass % of the resin composition,
the metal thin-film layer has a thickness of 12 nm or less,
the metal thin-film layer is a vapor deposited film formed from aluminum,
the polyphenylene ether resin (A) includes a polyphenylene ether (i) and a compound (ii) being at least one compound selected from the group consisting of: an organophosphorus compound having, in molecules thereof, a chemical structure represented by formula (I) or (II), shown below, 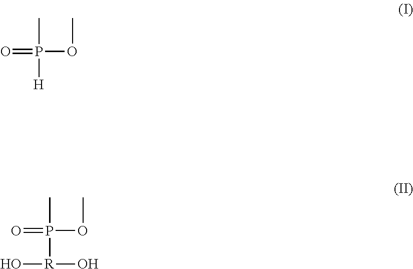
where R in formula (II) is a trivalent saturated hydrocarbon group having a carbon number of 1 to 8 or a trivalent aromatic hydrocarbon group having a carbon number of 6 to 12; and a phosphonic acid, phosphonic acid ester, phosphinic acid, phosphinic acid ester, monocarboxylic acid, sulfonic acid, sulfinic acid, or carbonate other than the organophosphorus compound in amounts of 95 mass % to 99.95 mass % of the component (i) and 0.05 mass % to 5 mass % of the component (ii) relative to 100 mass %, in total, of the components (i) and (ii), and.
the polyphenylene ether (i) includes at least one structural unit selected from the group consisting of chemical formulae (1), (2), and (3), shown below, 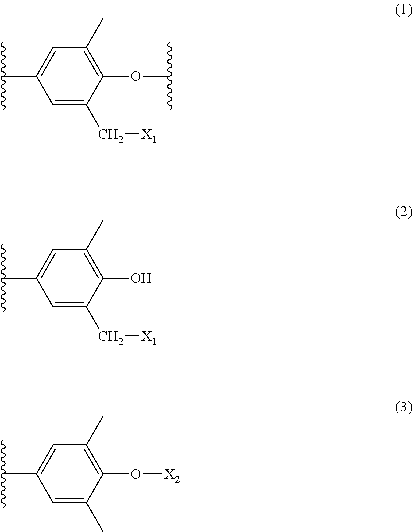
where X₁ in chemical formulae (1) and (2) is one group selected from 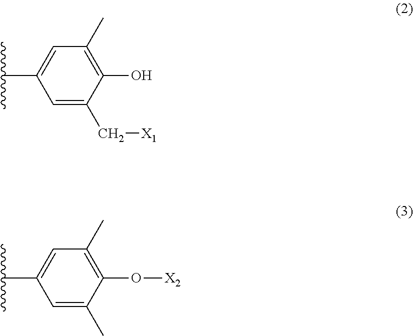
with R₁ and R₂ in X₁ each being, independently of one another, a substituent having a carbon number of 1 or more, and
X₂ in chemical formula (3) is one group selected from the group consisting of 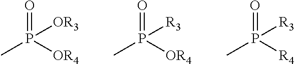
with R₃ and R₄ in X₂ each being, independently of one another, a group selected from the group consisting of a hydrogen atom, an alkyl group, an aryl group, an alkylamino group, and an arylamino group, where R₃ and R₄ may form a cyclic structure through bonding of respective carbon atoms included therein, and chemical formula (3) does not substantially include an unsaturated double bond other than an aromatic ring unsaturated double bond.

14. The laminated molded article according to claim 13, wherein
the at least one structural unit selected from the group consisting of chemical formulae (1), (2), and (3) is contained in a ratio of 0.01 units to 10.0 units per 100 monomer units composing the polyphenylene ether (i).

15. The laminated molded article according to claim 13, wherein
a ratio of a structural unit represented by chemical formula (1) relative to a structural unit represented by chemical formula (2) in the polyphenylene ether (i) is 0 mol % to 30 mol %.

16. The laminated molded article according to claim 13, wherein
the polyphenylene ether (i) includes a structural unit represented by chemical formula (3) and either or both of a structural unit represented by chemical formula (1) and a structural unit represented by chemical formula (2).

17. The laminated molded article according to claim 13, wherein
the polyphenylene ether (i) includes at least one structural unit selected from the group consisting of chemical formulae (4), (5), and (6), shown below, 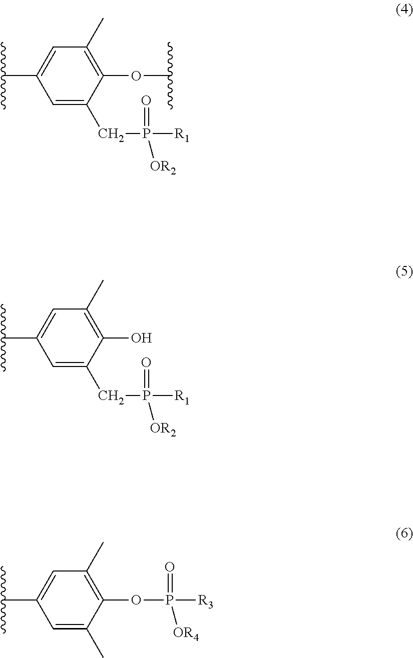
where R₁ and R₂ in chemical formulae (4) and (5) are each, independently of one another, a substituent having a carbon number of 1 or more, R₃ and R₄ in chemical formula (6) are each, independently of one another, a group selected from the group consisting of a hydrogen atom, an alkyl group, an aryl group, an alkylamino group, and an arylamino group, R₃ and R₄ may form a cyclic structure through bonding of respective carbon atoms included therein, and chemical formula (6) does not substantially include an unsaturated double bond other than an aromatic ring unsaturated double bond.

18. The laminated molded article according to claim 13, wherein
the at least one structural unit selected from the group consisting of chemical formulae (1), (2), and (3) is contained in a ratio of 0.01 units to 10.0 units per 100 monomer units composing the polyphenylene ether (i),
a ratio of a structural unit represented by chemical formula (1) relative to a structural unit represented by chemical formula (2) in the polyphenylene ether (i) is 0 mol % to 30 mol %, and
the polyphenylene ether (i) includes a structural unit represented by chemical formula (3) and either or both of a structural unit represented by chemical formula (1) and a structural unit represented by chemical formula (2).

19. The laminated molded article according to claim 13, wherein
the at least one structural unit selected from the group consisting of chemical formulae (1), (2), and (3) is contained in a ratio of 0.01 units to 10.0 units per 100 monomer units composing the polyphenylene ether (i),
a ratio of a structural unit represented by chemical formula (1) relative to a structural unit represented by chemical formula (2) in the polyphenylene ether (i) is 0 mol % to 30 mol %,
the polyphenylene ether (i) includes a structural unit represented by chemical formula (3) and either or both of a structural unit represented by chemical formula (1) and a structural unit represented by chemical formula (2), and
the polyphenylene ether (i) includes at least one structural unit selected from the group consisting of chemical formulae (4), (5), and (6), shown below, 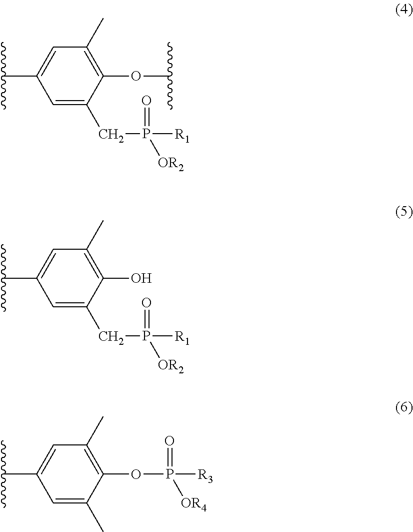
where R₁ and R₂ in chemical formulae (4) and (5) are each, independently of one another, a substituent having a carbon number of 1 or more, R₃ and R₄ in chemical formula (6) are each, independently of one another, a group selected from the group consisting of a hydrogen atom, an alkyl group, an aryl group, an alkylamino group, and an arylamino group, R₃ and R₄ may form a cyclic structure through bonding of respective carbon atoms included therein, and chemical formula (6) does not substantially include an unsaturated double bond other than an aromatic ring unsaturated double bond.
